(19) United States
(12) Patent Application Publication
(10) Pub. No.: US 2025/0355342 A1
(43) Pub. Date: Nov. 20, 2025

(54) PELLICLE ASSEMBLY MOUNTING FOR LITHOGRAPHY MASK

(71) Applicant: Taiwan Semiconductor Manufacturing Co., Ltd., Hsinchu (TW)

(72) Inventors: Kun-Lung HSIEH, Hsinchu (TW); Hao-En LUO, Hsinchu (TW); Shang-Cheng TSAI, Hsinchu (TW); Chih-Wei WEN, Hsinchu (TW)

(73) Assignee: Taiwan Semiconductor Manufacturing Co., Ltd., Hsinchu (TW)

(21) Appl. No.: 19/290,762

(22) Filed: Aug. 5, 2025

Related U.S. Application Data
(63) Continuation of application No. 18/592,405, filed on Feb. 29, 2024.
(60) Provisional application No. 63/594,204, filed on Oct. 30, 2023.

(51) Int. Cl. G03F 1/24

(52) U.S. Cl. CPC G03F 1/24

(57) ABSTRACT

An extreme ultraviolet mask including a substrate, a reflective multilayer stack on the substrate and patterned absorber layer on the reflective multilayer stack is provided with a pellicle membrane frame attached to the substrate. In some embodiments, the pellicle membrane frame is attached to the substrate using an adhesive between the pellicle membrane frame and the substrate. In some embodiments, the pellicle membrane frame is located in a trench formed in the reflective multilayer stack and patterned absorber layer. In other embodiments, the pellicle membrane frame not located in a trench formed in the reflective multilayer stack and patterned absorber layer.

### BACKGROUND

The semiconductor industry has experienced exponential growth. Technological advances in materials and design have produced generations of integrated circuits (ICs), where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1J are cross-sectional views of an extreme ultraviolet (EUV) mask, in accordance with multiple embodiments of the present disclosure.

FIG. 2A and FIG. 2B are a flowchart of a method for fabricating the EUV mask and attaching a pellicle frame carrying a pellicle membrane a substrate to provide the EUV mask of FIG. 1A-1J, in accordance with some embodiments.

FIGS. 3A-3M are cross-sectional views of an EUV mask at various stages of the fabrication process of FIGS. 2A and 2B, in accordance with some embodiments.

FIG. 4 is a cross-sectional view of an extreme ultraviolet (EUV) mask, in accordance with a second embodiment.

FIG. 5 is a flowchart of a method of using an EUV mask in accordance with some embodiments.

FIG. 6 includes schematic cross sectional views of the attachment of a pellicle membrane to a pellicle frame and attachment of the pellicle frame to a mask substrate in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the manufacture of integrated circuits (ICs), patterns representing different layers of the ICs are fabricated using a series of reusable photomasks (also referred to herein as photolithography masks or masks) in order to transfer the design of each layer of the ICs onto a semiconductor substrate during the semiconductor device fabrication process.

With the shrinkage in IC size, extreme ultraviolet (EUV) light with a wavelength of 13.5 nm is employed in, for example, a lithographic process to enable transfer of very small patterns (e.g., nanometer-scale patterns) from a mask to a semiconductor wafer. Because most materials are highly absorbing at the wavelength of 13.5 nm, EUV lithography utilizes a reflective-type EUV mask having a reflective multilayer to reflect the incident EUV light and an absorber layer on top of the reflective multilayer to absorb radiation in areas where light is not supposed to be reflected by the mask. The reflective multilayer and absorber layer are on a low thermal expansion material substrate. The reflective multilayer reflects the incident EUV light and the patterned absorber layer on top of the reflective multilayer absorbs light in areas where light is not supposed to be reflected by the mask. The mask pattern is defined by the absorber layer and is transferred to a semiconductor wafer by reflecting EUV light of portions of a reflective surface of the EUV mask.

In EUV lithography, to separate the reflected light from the incident light, the EUV mask is illuminated with obliquely incident light that is tilted at a 6-degree angle from normal. The oblique incident EUV light is reflected by the reflective multilayer or absorbed by the absorber layer. In the fabrication of the EUV mask, on that occasion, if the absorber layer is thick, at the time of EUV lithography, a shadow may be formed. For example, the reflected light may be scattered by portions of the absorber layer. The mask shadowing effects, also known as mask 3D effects, can result in unwanted feature-size dependent focus and pattern placement shifts. The mask 3D effects become worse as the technology node advances. With shrinking pattern size, mask 3D effects become stronger, such as horizontal/vertical shadowing.

An ongoing desire to have more densely packed integrated devices has resulted in changes to the photolithography process in order to form smaller individual feature sizes. The minimum feature size or “critical dimension” (CD) obtainable by a process is determined approximately by the formula CD=k₁*λ/NA, where k₁ is a process-specific coefficient, λ is the wavelength of applied light/energy, and NA is the numerical aperture of the optical lens as seen from the substrate or wafer.

For fabrication of dense features with a given value of k₁, the ability to project a usable image of a small feature onto a wafer is limited by the wavelength λ and the ability of the projection optics to capture enough diffraction orders from an illuminated mask. When either dense features or isolated features are made from a photomask or a reticle of a certain size and/or shape, the transitions between light and dark at the edges of the projected image may not be sufficiently sharply defined to correctly form target photoresist patterns. This may result, among other things, in reducing the contrast of aerial images and also the quality of resulting photoresist profiles. As a result, features 150 nm or below in size may need to utilize phase shifting masks (PSMs) or techniques to enhance the image quality at the wafer, e.g., sharpening edges of features to improve resist profiles.

Phase-shifting generally involves selectively changing phases of part of the energy passing through a photomask/reticle so that the phase-shifted energy is additive or subtractive with energy that is not phase-shifted at the surface of the material on the wafer that is to be exposed and patterned. By carefully controlling the shape, location, and phase shift angle of mask features, the resulting photoresist patterns can have more precisely defined edges. As the feature size reduces, an imbalance of transmission intensity between the 0° and 180° phase portions and a phase shift that varies from 180° can result in significant critical dimension (CD) variation and placement errors for the photoresist pattern.

Phase shifts may be obtained in a number of ways. For example, one process known as attenuated phase shifting (AttPSM) utilizes a mask that includes a layer of non-opaque material that causes light passing through the non-opaque material to change in phase compared to light passing through transparent parts of the mask. In addition, the non-opaque material can adjust the amount (intensity/magnitude) of light transmitted through the non-opaque material compared to the amount of light transmitted through transparent portions of the mask.

Another technique is known as alternating phase shift, where the transparent mask material (e.g., quartz or SiO₂ substrate) is sized (e.g., etched) to have regions of different depths or thicknesses. The depths are selected to cause a desired relative phase difference in light passing through the regions of different depths/thicknesses. The resulting mask is referred to as an “alternating phase shift mask” or “alternating phase shifting mask” (AltPSM). AttPSMs and AltPSMs are referred to herein as “APSM.” The portion of the AltPSM having the thicker depth is referred to as the 0° phase portion, while the portion of the AltPSM having the lesser depth is referred to as the 1800 phase portion. The depth difference allows the light to travel half of the wavelength in the transparent material, generating a phase difference of 1800 between 0° and 1800 portions. In some implementations, a patterned phase shifting material is located above the portions of the transparent mask substrate that has not been etched to different depths. The phase shifting material is a material that affects the phase of the light passing through the phase shifting material such that the phase of the light passing through the phase shifting material is shifted relative to the phase of the light that does not pass through the phase shifting material, e.g., passes only through the transparent mask substrate material without passing through the phase shifting material. The phase shifting material can also reduce the amount of light transmitted through the phase shifting material relative to the amount of incident light that passes through portions of the mask not covered by the phase shifting material.

In embodiments of the present disclosure, a pellicle membrane frame is attached to a substrate of a photolithography mask with or without the use of an adhesive. Unlike other masks used in photolithographic processes where a pellicle membrane frame is attached to an absorber layer of the photolithography mask, embodiments in accordance with the present disclosure have the pellicle membrane frame attached directly to the substrate or a thermal conductive resistance material formed on the substrate. In some embodiments of the present disclosure, the pellicle membrane frame is positioned in a trench formed in a reflective multilayer stack, capping layer and absorber layer of the mask and is attached directly to the substrate at the bottom of such trench. Positioning the pellicle membrane frame in a trench and attaching it to the substrate at the bottom of the trench helps to reduce the exposure of the adhesive to the detrimental effects of incident radiation used during photolithographic processes in which the photolithography mask is employed. Exposure of the adhesive to the incident radiation can degrade the adhesive in ways that negatively impact the useful lifetime of the pellicle frame.

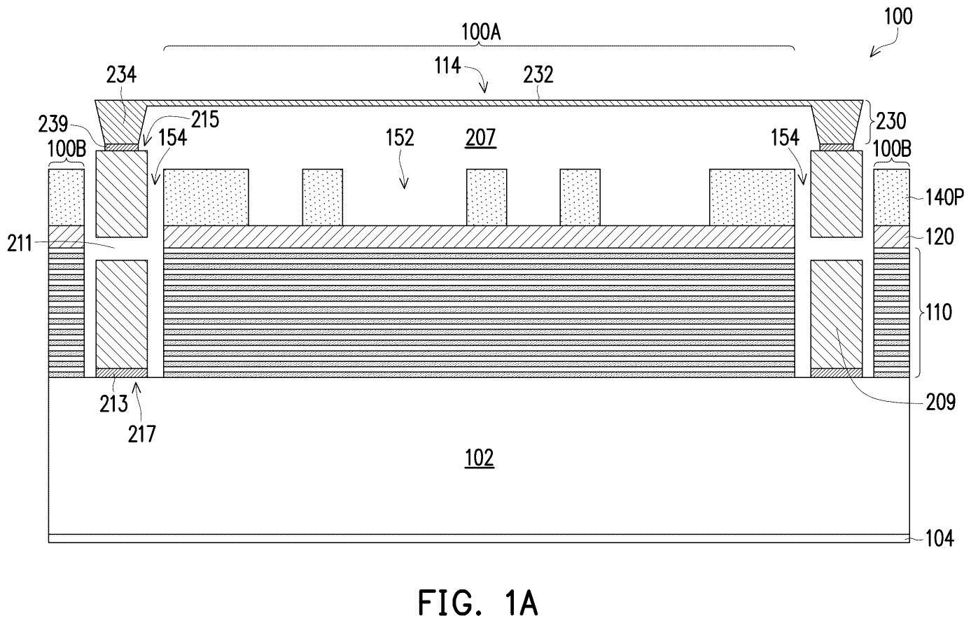

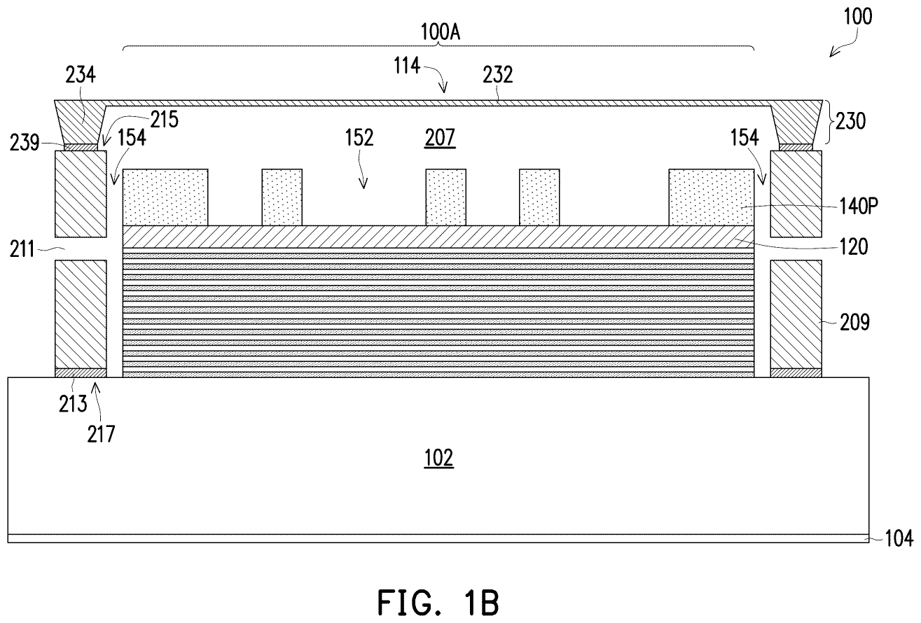

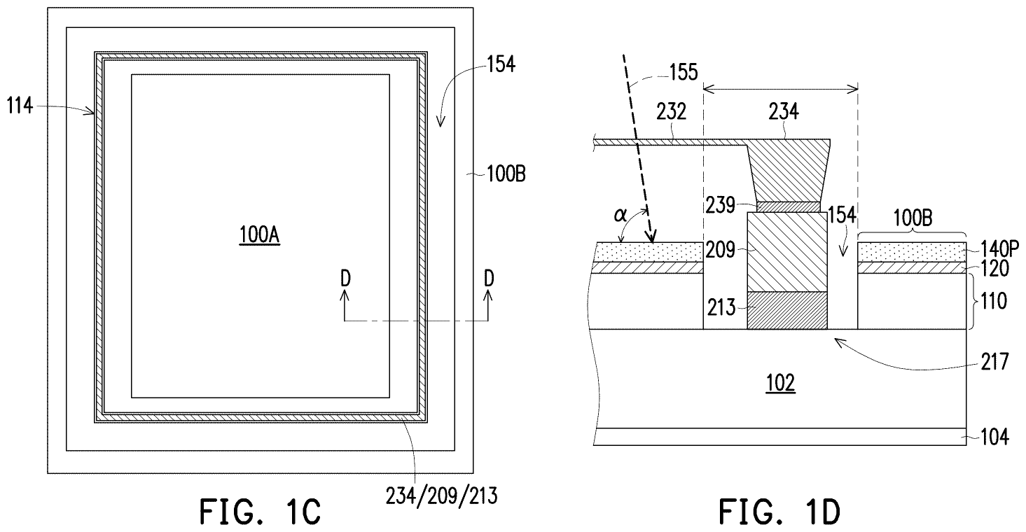

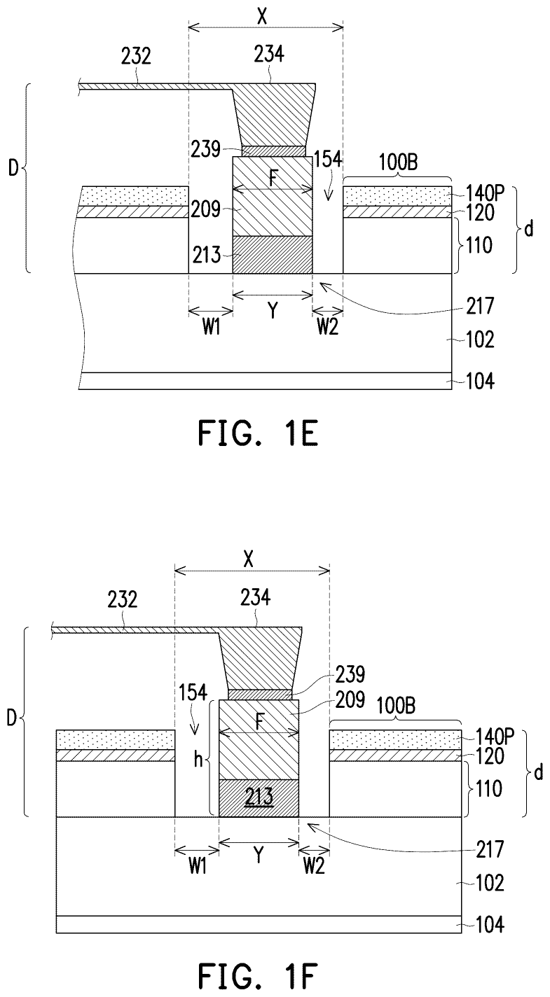

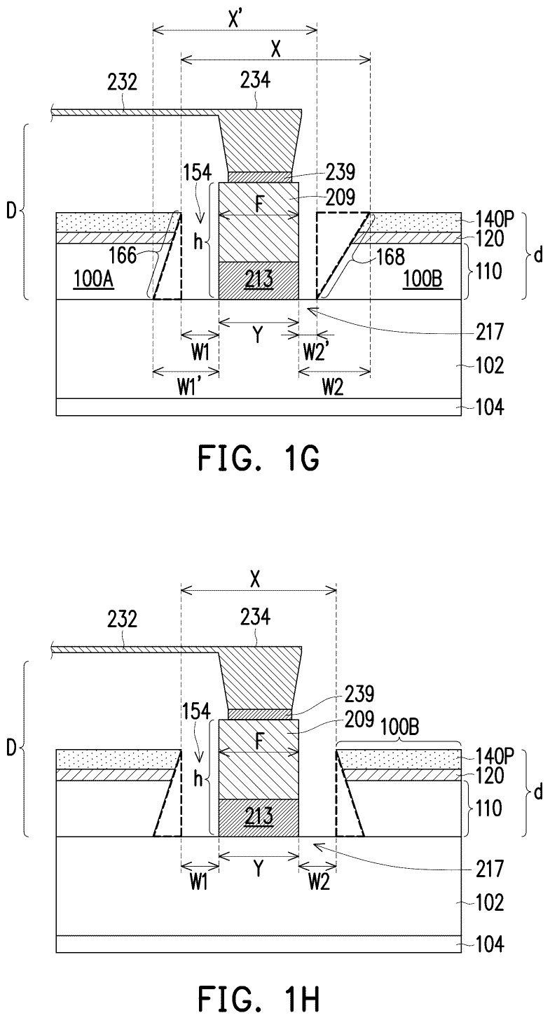

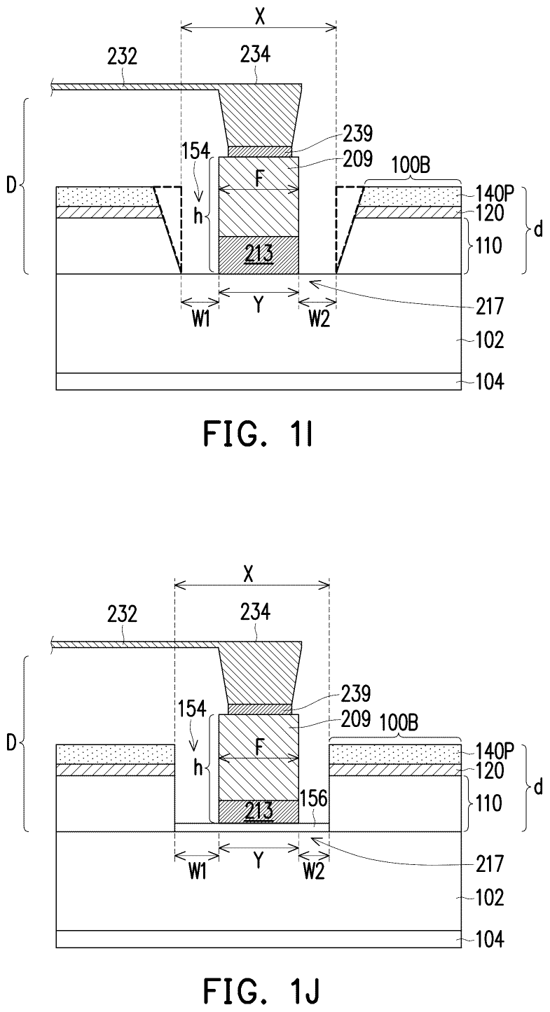

FIG. 1A is a cross-sectional view of an EUV mask 100, in accordance with a first embodiment of the present disclosure. Embodiments of the present disclosure are not limited to EUV masks, for example embodiments of the present disclosure are applicable to photomasks used in processes that do not utilize EUV radiation. Referring to FIG. 1A, the EUV mask 100 includes a substrate 102, a reflective multilayer stack 110 over a front surface of the substrate 102, an optional capping layer 120 over the reflective multilayer stack 110 and a patterned absorber layer 140P over the optional capping layer 120. In some embodiments an optional patterned buffer layer (not shown) can be provided between the capping layer 120 and the patterned absorber layer 140P. The EUV mask 100 further includes a conductive layer 104 over a back surface of the substrate 102 opposite the front surface.

The patterned absorber layer 140P and the patterned buffer layer, when present, include a pattern of openings 152 that correspond to circuit patterns to be formed on a semiconductor wafer. The pattern of openings 152 is located in a pattern region 100A of the EUV mask 100, exposing a surface of the capping layer 120. The pattern region 100A is surrounded by a peripheral region 100B of the EUV mask 100. The peripheral region 100B corresponds to a non-patterned region of the EUV mask 100 that is not used in an exposing process during IC fabrication. In some embodiments, the pattern region 100A of EUV mask 100 is located at a central region of the substrate 102, and the peripheral region 100B is located at an edge portion of the substrate 102. The pattern region 100A is separated from the peripheral region 100B by trenches 154. The trenches 154 extend through the patterned absorber layer 140P, the capping layer 120, and the reflective multilayer stack 110, exposing the front surface of the substrate 102.

In accordance with some embodiments of the present disclosure, patterned absorber layer 140P is a layer of absorber material such as tantalum boron nitride, hafnium oxide, silicon nitride or tantalum nitride. In some embodiments, the absorber material is an alloy of a transition metal, e.g., ruthenium (Ru), chromium (Cr), platinum (Pt), gold (Au), iridium (Ir), titanium (Ti), niobium (Nb), rhodium (Rh), molybdenum (Mo), tungsten (W), or palladium (Pd), and at least one alloying element selected from ruthenium (Ru), chromium (Cr), tantalum (Ta), platinum (Pt), palladium (Pd), tungsten (W), gold (Au), iridium (Ir), titanium (Ti), niobium (Nb), rhodium (Rh), molybdenum (Mo), hafnium (Hf), boron (B), nitrogen (N), silicon (Si), zirconium (Zr), or vanadium (V). Embodiments in accordance with the present disclosure are not limited to use of the foregoing absorber materials. For example, in other embodiments of the present disclosure, different absorber materials can be used.

In accordance with some embodiments of the present disclosure, patterned absorber layer 140P includes a first layer of absorber material and a second layer of absorber material different from the first layer of absorber material, the absorber material of the first layer having an index of refraction smaller than 0.95 and an extinction coefficient (k) greater than 0.01. The extinction coefficient k is a function of decay in the amplitude of a light wave propagating in the absorber material. Examples of an absorber material that has an index of refraction smaller than 0.95 and an extinction coefficient greater than 0.01 include an alloy of ruthenium (Ru), chromium (Cr), tantalum (Ta), platinum (Pt), gold (Au), iridium (Ir), titanium (Ti), niobium (Nb), rhodium (Rh), molybdenum (Mo), tungsten (W), or palladium (Pd), and at least one alloying element selected from ruthenium (Ru), chromium (Cr), tantalum (Ta), platinum (Pt), palladium (Pd), tungsten (W), gold (Au), iridium (Ir), titanium (Ti), niobium (Nb), rhodium (Rh), molybdenum (Mo), hafnium (Hf), boron (B), nitrogen (N), silicon (Si), zirconium (Zr), or vanadium (V).

In accordance with embodiments of the present disclosure, the reflective multilayer stack 110 includes alternating layers of materials that for EUV embodiments, provide effective reflection of EUV radiation. Examples of suitable materials include molybdenum and silicon. Embodiments of the present disclosure are not limited to reflective multi-stack layers that the use of molybdenum and silicon. For example, embodiments of the present disclosure are applicable to reflective multi-stack alternating layers of materials other than molybdenum and silicon.

In accordance with embodiments of the present disclosure, capping layer 120 includes materials effective to retard oxidation of the materials of the multilayer stack 110 and provide suitable loss of EUV radiation reflected by the multilayer stack 110. Examples of such materials include TaO, TaBO, ruthenium containing compounds or combinations thereof.

In accordance with embodiments of the present disclosure, substrate 102 includes materials such as Si, silicon dioxide, titanium, or combinations thereof. One example of a material for substrate 102 includes a low thermal expansion material substrate, such as TiO₂ doped SiO₂.

FIG. 1A also illustrates a cross-sectional view of a pellicle 114 including a pellicle membrane 232 supported on a pellicle frame 209 in accordance with some embodiments of the present disclosure. As illustrated in FIG. 1A, the photomask 100 may include a mask substrate 102 and a patterned absorber layer 140P positioned over the mask substrate 102.

In some examples, the mask substrate 102 includes a transparent substrate, such as fused silica that is relatively free of defects, borosilicate glass, soda-lime glass, calcium fluoride, low thermal expansion material, ultra-low thermal expansion material, or other applicable materials. The patterned absorber layer 140P may be positioned over the mask substrate 102 as discussed above and may be designed according to the integrated circuit features to be formed over a semiconductor substrate during a lithography process. The patterned absorber layer 140P may be formed by depositing a material layer and patterning the material layer to have one or more openings 152 where beams of radiation may travel through without being absorbed, and one or more absorption areas which may completely or partially block the beams of radiation.

In addition to the materials described above for absorber layer 140P, absorber layer 140P may include metal, metal alloy, metal silicide, metal nitride, metal oxide, metal oxynitride, or other applicable materials. Examples of materials that may be used to form the absorber layer 140P may include, but are not limited to, Cr, MoₓSi_{y}, TaₓSi_{y}, Mo, NbₓO_{y}, Ti, Ta, CrₓN_{y}, MoₓO_{y}, MoₓN_{y}, CrₓO_{y}, TiₓN_{y}, ZrₓN_{y}, TiₓO_{y}, TaₓN_{y}, TaₓO_{y}, SiₓO_{y}, NbₓN_{y}, ZrₓN_{y}, AlₓO_{y}N_{z}, TaₓB_{y}O_{z}, TaₓB_{y}N_{z}, AgₓO_{y}, AgₓN_{y}, Ni, NiₓO_{y}, NiₓO_{y}N_{z}, and/or the like. The compound x/y/z ratio is not limited.

In some embodiments, the photomask 100 is an EUV mask. However, in other embodiments, the photomask 100 may be a photomask for use in photolithography processes that utilize radiation other than EUV, for example photolithography processes that utilize UV radiation.

As illustrated in FIG. 1A, the pellicle 114 may be positioned over the patterned absorber layer 140P, thereby forming an enclosed inner volume 207 that is enclosed by the pellicle 114, the patterned absorber layer 140P and the substrate 102.

In the illustrated embodiments, the pellicle membrane 232 is supported by a pellicle frame 209 that may be positioned over at least one of the substrate 102, patterned absorber layer 140P, the reflective multilayer stack 110 and the capping layer 120. The pellicle frame 209 may be designed in various dimensions, shapes, and configurations. In some embodiments, the pellicle frame 209 may have a round shape, a rectangular shape, or any other suitable shape. In some embodiments, the pellicle frame 209 may be formed from Ti, Si, SiC, SiN, titanium oxide, glass, a low coefficient of thermal expansion material (such as an Al alloy, a Ti alloy, nickel-irons such as Invar®, nickel-cobalt ferrous alloys such as Kovar®, or the like), another suitable material, or a combination thereof. In some embodiments, suitable processes for forming the pellicle frame 209 may include machining processes, sintering processes, photochemical etching processes, other applicable processes, or a combination thereof. In the illustrated embodiments, pellicle frame 209 is positioned within trenches 154. As described in more detail below, a first end of the pellicle frame 209 is attached directly to substrate 102 of photomask 100. In some embodiments, the first end of the pellicle frame attached directly to the substrate 102 is positioned below the capping layer 120 and below the patterned absorber layer 140P.

As further illustrated in FIG. 1A, the pellicle frame 209 may further include a vent structure 211 extending through the pellicle frame 209. In some embodiments, the vent structure 211 may comprise one or more apertures formed through the pellicle frame 209. The apertures may take any shape, including circular apertures, rectangular apertures, slit-shaped apertures, other shapes, or any combination thereof. The apertures may allow for a flow of air or other gas through a portion of the pellicle frame 209. Vent structure 211 serves to equalize air pressure between the open space bounded by the pellicle frame 209, the pellicle membrane assembly 230 and substrate 102 and the environment outside the pellicle frame 209, pellicle membrane assembly 230 and substrate 102. In some embodiments, the apertures may include filters to minimize passage of outside particles through the vent structure 211. In some embodiments, the vent structure 211 may prevent the pellicle membrane 232 from rupturing during the EUV lithography process due to an increase in pressure within inner volume 207.

As further illustrated in FIG. 1A, in accordance with embodiments of the present disclosure, pellicle frame 209 includes two ends, an upper end 215 and a lower end 217. Lower end 217 of pellicle frame 209 is attached to substrate 102, for example, directly attached to substrate 102 by a pellicle frame adhesive 213. Upper end 215 of pellicle frame 209 is attached to pellicle 114, for example utilizing a pellicle membrane adhesive 239. In the embodiment of FIG. 1A, lower end 217 is positioned at a level below capping layer 120 and below patterned absorber layer 140P. In some embodiments, the pellicle frame adhesive 213 and pellicle membrane adhesive 239 are formed of an adhesive that is susceptible to degradation by exposure to EUV radiation or excessive temperatures. For example, these adhesives may be formed from a crosslink type adhesive, a thermoplastic elastomer type adhesive, a polystyrene type adhesive, an acrylic type adhesive, a silicon-based adhesive, an epoxy type adhesive, or a combination thereof. Specific examples of materials for use as pellicle frame adhesive 213 and/or pellicle membrane adhesive 239 include acrylic adhesives, silicon, and styrene ethylene butadiene styrene rubbers (SEBS) combinations thereof.

In some embodiments, a surface treatment may be performed on the upper and lower ends of pellicle frame 209 to enhance the adhesion of the pellicle frame 209 to the pellicle frame adhesive 213 and pellicle membrane adhesive 239. In some examples, the surface treatment may include an oxygen plasma treatment, another applicable treatment, or a combination thereof. However, in other examples, no surface treatment may be performed on the pellicle frame 209.

As further illustrated in FIG. 1A, the pellicle 114 includes a pellicle membrane assembly 230 including a pellicle membrane 232 and a membrane border 234 positioned around the periphery of the pellicle membrane 232 and over the pellicle frame 209. The pellicle membrane 232 extends over the pattern region of the patterned absorber layer 140P to protect the pattern region from contaminant particles. Particles unintentionally deposited on the pattern region of the photomask 100 may introduce defects and result in degradation of the transferred patterns. Particles may be introduced by any of a variety of ways, such as during, a cleaning process, and/or during handling of the photomask 100. By keeping the contaminant particles out of the focal plane of the photomask 100, a high fidelity pattern transfer from the photomask 100 to the semiconductor wafer can be achieved.

As illustrated in FIG. 1A, a pellicle membrane adhesive 239 may be positioned between the membrane border 234 and the upper end 215 of pellicle frame 209, attaching the pellicle membrane 232 to the upper end 215 of pellicle frame 209. In some embodiments, the pellicle membrane adhesive 239 may be formed from a thermoplastic elastomer type adhesive, a polystyrene type adhesive, an acrylic type adhesive, a silicon-based adhesive, an epoxy type adhesive, another suitable adhesive, or a combination thereof. In some embodiments, the pellicle membrane adhesive 239 may be formed from a material that is different from the material making up the pellicle frame adhesive 213.

The membrane border 234 may be attached around the periphery of the pellicle membrane 232, and thus mechanically supports the pellicle membrane 232. The membrane border 234 may, in turn, be mechanically supported by the upper end 215 of pellicle frame 209 when the photomask 100 is fully assembled. That is, the pellicle frame 209 may mechanically support the membrane border 234 and the pellicle membrane 232 on the substrate 102 of photomask 100.

In some embodiments, the membrane border 234 and/or membrane 232 may be formed from Si. In further examples, the membrane border 234 may be formed from boron carbide, graphene, carbon nanotube, SiC, SiN, SiO₂, SiON, MoSi, Zr, Nb, Mo, Cd, Ru, Ti, Al, Mg, V, Hf, Ge, Mn, Cr, W, Ta, Ir, Zn, Cu, F, Co, Au, Pt, Sn, Ni, Te, Ag, another suitable material, an allotrope of any of these materials, or a combination thereof.

FIG. 1B illustrates an alternative embodiment of the embodiments of FIG. 1A. In the embodiment of FIG. 1B, the peripheral regions 100B are not present. In FIG. 1B features that are the same as features illustrated in FIG. 1A are identified by the same reference numerals.

FIG. 1C illustrates a top view of EUV mask 100 in FIG. 1A. FIG. 1D is an enlarged side elevation view of a portion of EUV mask 100 of FIG. 1C along line D-D. In accordance with embodiments of the present disclosure, EUV mask 100 includes pellicle frame 209 which includes a lower end 217 is secured to substrate 102 by a pellicle frame adhesive 213. Pellicle frame adhesive 213 directly contacts an upper surface of substrate 102 to and directly contacts the lower end 217 of pellicle frame 209. In the illustrated embodiment, pellicle frame adhesive 213 is positioned at the bottom of the trench 154. In the additional embodiments, one or more other layers of material can be present on the upper surface of substrate. In such embodiments, an upper surface of such other layers of material defines a bottom of trench 154. In such embodiments, pellicle frame adhesive 213 directly contacts an upper surface of the uppermost layer of the other layers of material on the substrate 102. In FIG. 1D, upper surface (215 in FIG. 1A) of pellicle frame 209 is attached to pellicle membrane border 234 by pellicle membrane adhesive 239. As illustrated in FIG. 1D, pellicle frame adhesive 213 is below an upper surface of reflective multilayer stack 110 and is below an upper surface of patterned absorber layer 140P. In contrast, in some embodiments, pellicle membrane adhesive 239 and upper end 215 of pellicle frame 209 are located above the upper surface of patterned absorber layer 140P. In FIG. 1D, EUV radiation impinging on an upper surface of patterned absorber layer 140P is represented by ray 155 which has an angle of incidence relative to an upper surface of patterned absorber layer 140P of a. In some embodiments, a is equal to about 6°; however, embodiments in accordance with the present disclosure include angle of incidence is that are less than or greater than 6°.

Adhesives used to secure pellicle frame 209 to the substrate 102, i.e., pellicle frame adhesive 213, can be susceptible to deterioration by direct exposure to EUV radiation, reflected EUV radiation and/or excessive thermal energy. For example, when pellicle frame adhesive 213 is exposed to an excessive amount of EUV radiation or thermal energy, the adhesive property of the pellicle frame adhesive 213 deteriorates, e.g., becomes weaker or fails. EUV radiation that impinges directly on pellicle frame adhesive 213 can cause deterioration of pellicle frame adhesive 213. Reflected EUV radiation that impinges on pellicle frame adhesive 213 can also cause deterioration of pellicle frame adhesive 213. EUV radiation that impinges on the pellicle frame adhesive 213 or portions of materials adjacent to pellicle frame adhesive 213, can cause the temperatures of the pellicle frame adhesive 213 or the portions of materials adjacent to pellicle frame adhesive 213 that are impinged by the EUV radiation to increase, sometimes to levels that cause deterioration of the pellicle frame adhesive 213. When the temperature of materials adjacent to pellicle frame adhesive 213 increase and thermal energy is conducted to the pellicle frame adhesive 213, the temperature of the pellicle frame adhesive 213 can increase to levels that cause deterioration of the pellicle frame adhesive 213. For example, some EUV masks attach a pellicle frame to an upper surface of an absorber material layer using an adhesive. When a pellicle frame is attached to an upper surface of an absorber material layer using adhesive, the useful lifetime of the EUV mask may be shortened due to exposure to the EUV radiation or thermal energy generated by the EUV radiation. Undesirably shortening the useful lifetime of the EUV mask, adversely affects the yield of the lithography process. EUV masks formed in accordance with some embodiments of the present disclosure, include pellicle membrane frame adhesive 213 located at a bottom of a trench 154 where the pellicle membrane frame adhesive 213 is less exposed to EUV radiation and thermal energy generated by the EUV radiation impinging on portions of the EUV mask compared to EUV masks that attached the lower end of a pellicle membrane frame to an upper surface of the absorber layer. In other embodiments described below in more detail, the outermost peripheral region 100B is omitted.

FIG. 1E is a reproduction of FIG. 1D with various dimension indicators F, X, Y, D, d, W1 and W2 added. F represents a width of pellicle frame 209. X represents a width of trench 154. Y represents the width of pellicle frame adhesive 213. D represents a distance between the bottom of trench 154 and underside of pellicle membrane 232, d represents a distance between an upper surface of the patterned absorber layer 140P and a bottom of trench 154, e.g., an upper surface of substrate 102. W1 represents a distance between an exterior edge of pattern region 100A and an interior side of pellicle frame 209. W2 represents a distance between an interior edge of peripheral region 100B and an opposite, exterior side of pellicle frame 209. In the embodiment of FIG. 1E, W1 and W2 are unequal. FIG. 1F is an embodiment of FIG. 1E where W1 and W2 are equal. The description above regarding the features of FIG. 1E is equally applicable to the features of FIG. 1F which are in common with FIG. 1E. Reference numbers have not been added to FIG. 1F to improve clarity of FIG. 1F.

In accordance with the embodiments of FIGS. 1E and 1F, F can vary, but in some embodiments, F is between 1 mm and 6 mm. In other embodiments, F is between 2 and 5 mm. F is not limited to values within the foregoing ranges. For example, F may be less than 1 mm or greater than 6 mm. X is equal to or greater than the sum of Y+W1+W2. The value of X can vary, but in some embodiments, X is between 1 mm and 25 mm. In other embodiments, X is between 2 mm and 20 mm. X is not limited to values within the foregoing ranges. For example, X may be less than 1 mm or greater than 25 mm. Y can be equal to or less than F. For example, Y is between 1 mm and 6 mm. In other embodiments, Y is between 2 and 5 mm. Y is not limited to values within the foregoing ranges. For example, Y may be less than 1 mm. D can vary and is typically equal to a value determined by the scanner in which the EUV mask is utilized. In some embodiments, D is greater than d, d is equal to or greater than the sum of the depth of absorber layer 140P+the depth of capping layer 120+the depth of multilayer stack 110 and any other layers on or between these layers. In some embodiments, a ratio of D:d is between 7000:1 to 3000:1. FIG. 1F identifies a height h for the combination of pellicle frame adhesive 213 and pellicle frame 209. Height h is greater than d and less than D. When height h is greater than d and less than D, an upper surface of pellicle frame 209 is above an upper surface of absorber layer 140P and below pellicle membrane 232. The value of W1 and W2 are a function of the tolerances of the tool used to mount pellicle frame 209 in trench 154, the tolerances of the processes used to form trench 154 and the need for any undercutting of the edge of pattern region 100A or peripheral region 100B. In some embodiments W1 and W2 are greater than 1 micrometer. In some embodiments, a ratio of X to W1 or W2 is between 21000:1 and 2000:1. In accordance with some embodiments of the present disclosure, W1 and/or W2 can be chosen to be small enough that, based on the angle of incidence of EUV radiation 155 and the value of d, an amount of EUV radiation that impinges on a bottom surface of trench 154 is minimized and/or an amount of EUV radiation that impinges on pellicle frame adhesive 213 or materials near pellicle frame adhesive 213 is minimized. Examples of materials near pellicle frame adhesive 213 include portions of substrate 102 adjacent pellicle frame adhesive and portions of pellicle frame 209 adjacent pellicle frame adhesive 213.

FIG. 1G illustrates an embodiment of the present disclosure wherein an exterior edge of pattern region 100A has been etched to provide an undercut surface 166 resulting in the exterior edge of pattern region being non-vertical. Undercut surface 166 includes an upper end at a distance W1 from an interior side of pellicle frame 209 and a lower end at a distance W1′ from the same interior side of the pellicle frame 209. FIG. 1G also illustrates an embodiment of the present disclosure wherein an interior edge of peripheral region 100B has been etched to provide an etched footing surface 168 resulting in the interior edge of peripheral region 100B being non-vertical. Etched footing surface 168 includes an upper end at a distance W2 from an exterior side of pellicle frame 209 and a lower end at a distance W2′ from the same exterior side of the pellicle frame 209. In FIG. 1G, trench 154 includes dimensions X and X′. In some embodiments X=X′ and in other embodiments X does not equal X′. An alternative to the embodiment illustrated in FIG. 1G includes both the edge of the pattern region 100A and the edge of peripheral region 100B including an undercut surface. This alterative is illustrated in FIG. 1H. In another embodiment, the edge of pattern region 100A and the edge of peripheral region 100B are etched to provide an etched footing surface. This alterative is illustrated in FIG. 1I.

In FIG. 1J, an alternative embodiment illustrated therein, shows a layer 156 of additional material, e.g., silicon or silicon dioxide, on substrate 102. Such layer 156 of additional material could be remnants from processing steps carried out prior to attachment of pellicle frame 209 to substrate 102 or it could be provided by a specific formation step. This additional material layer 156 can provide a further barrier to thermal energy being conducted to pellicle frame adhesive 213.

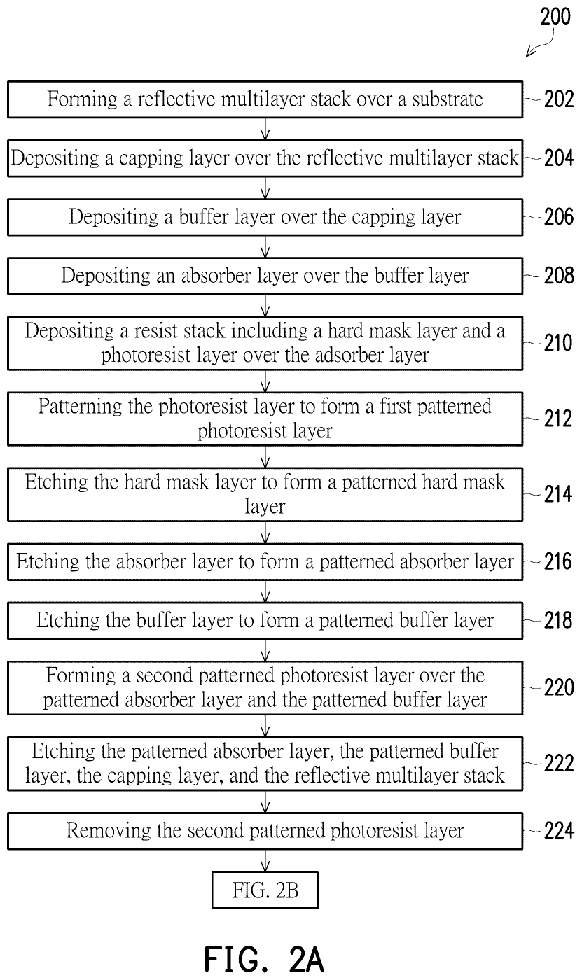

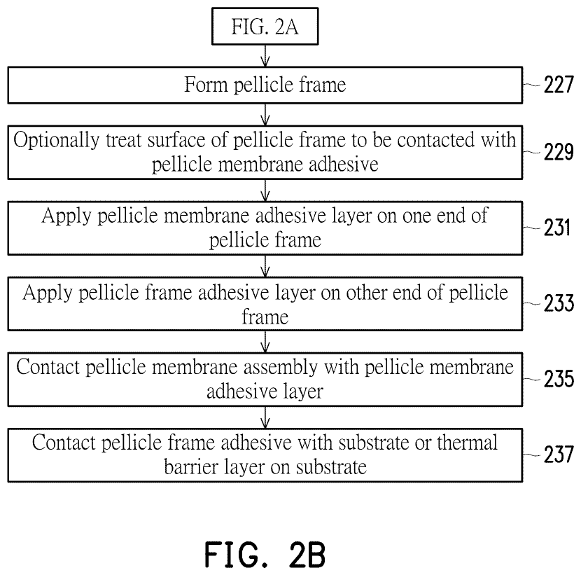

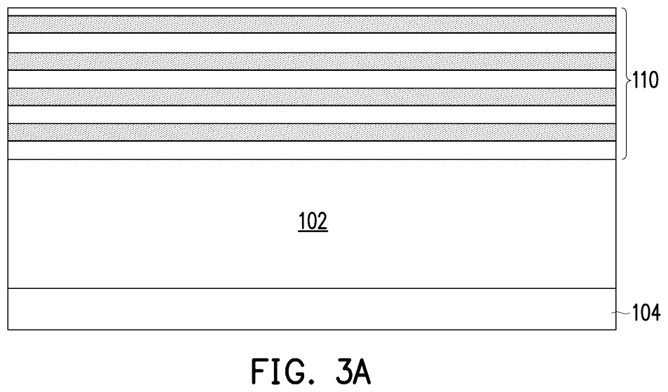

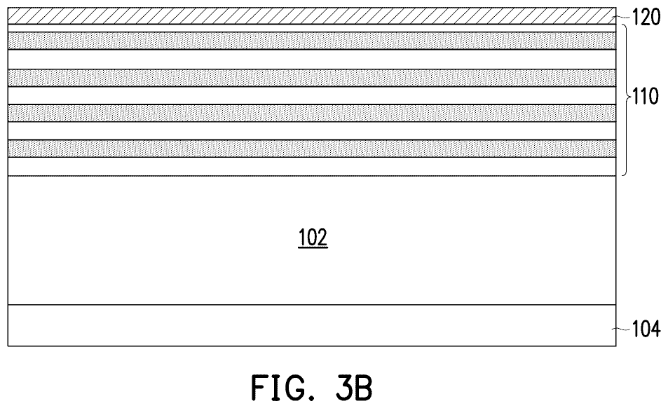

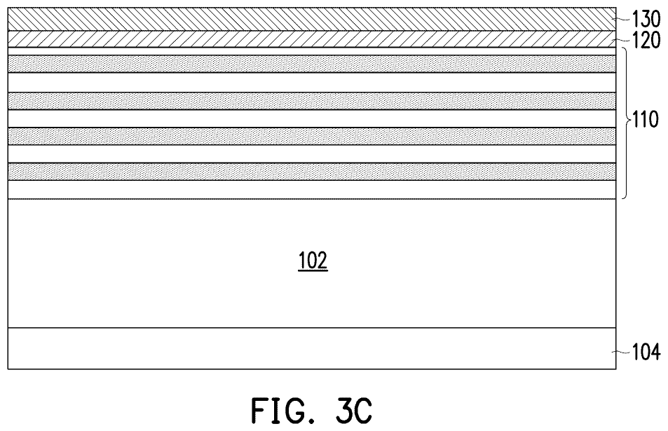

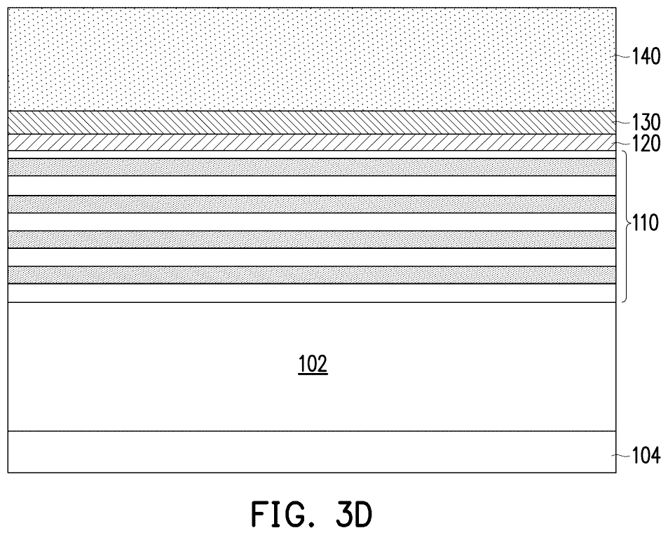

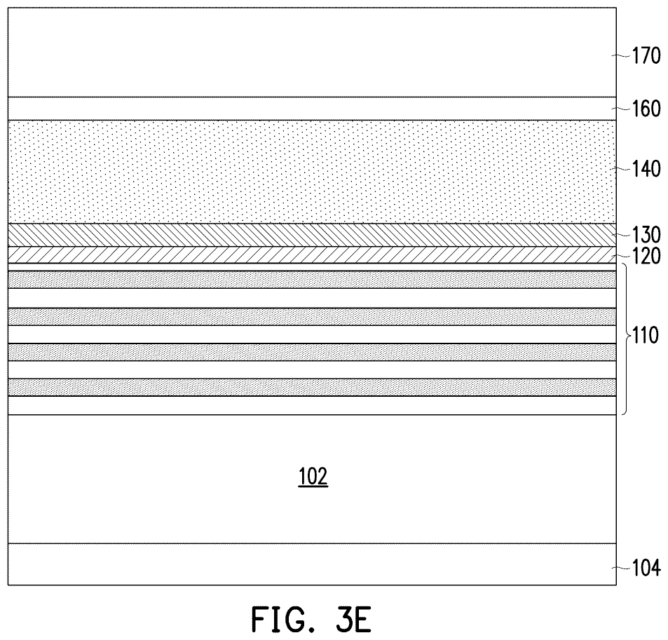

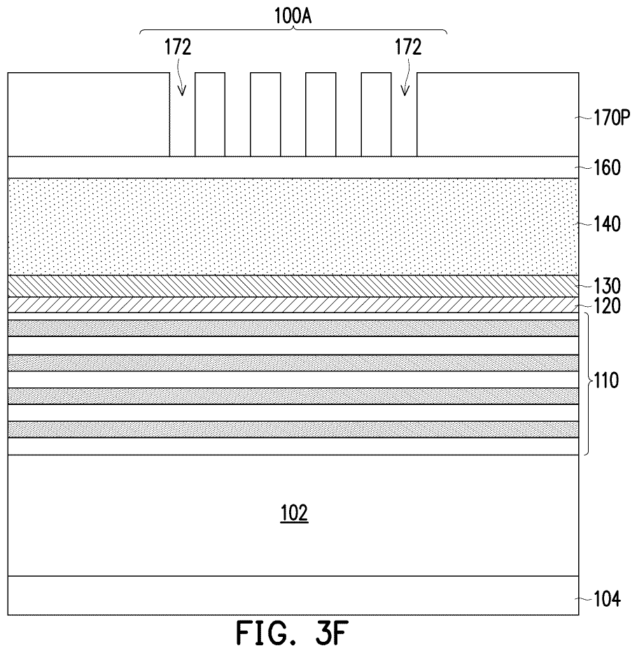

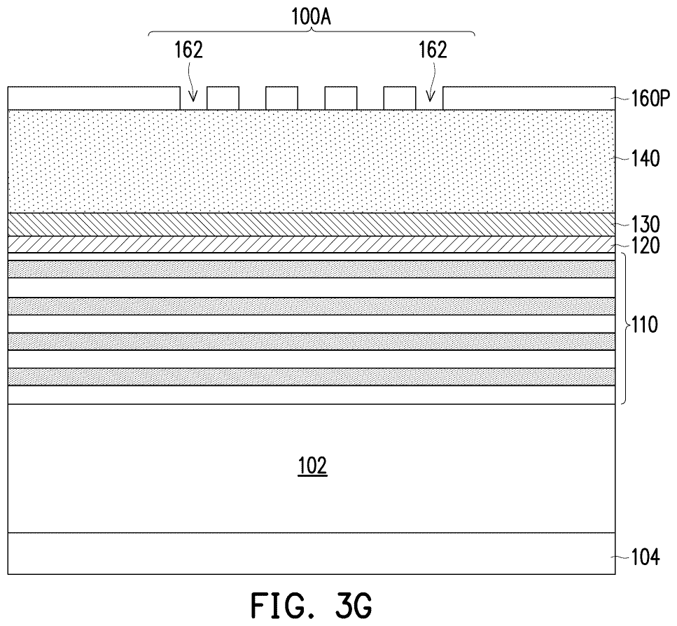

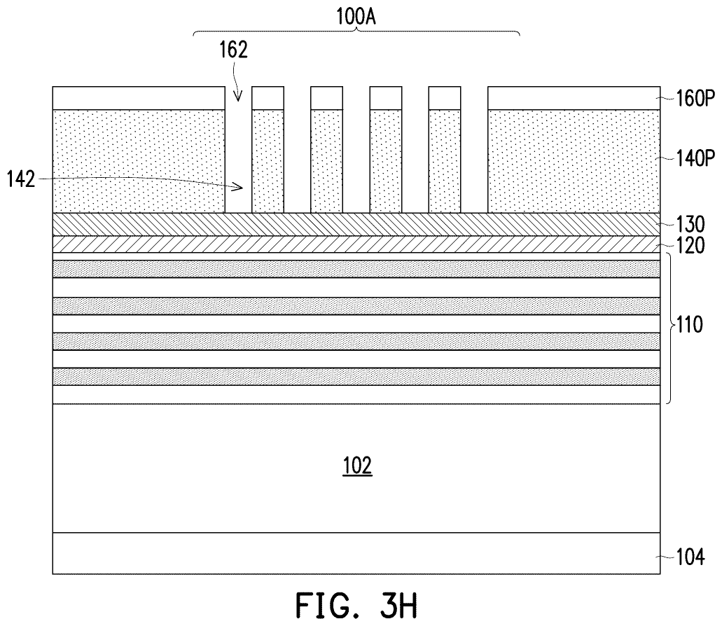

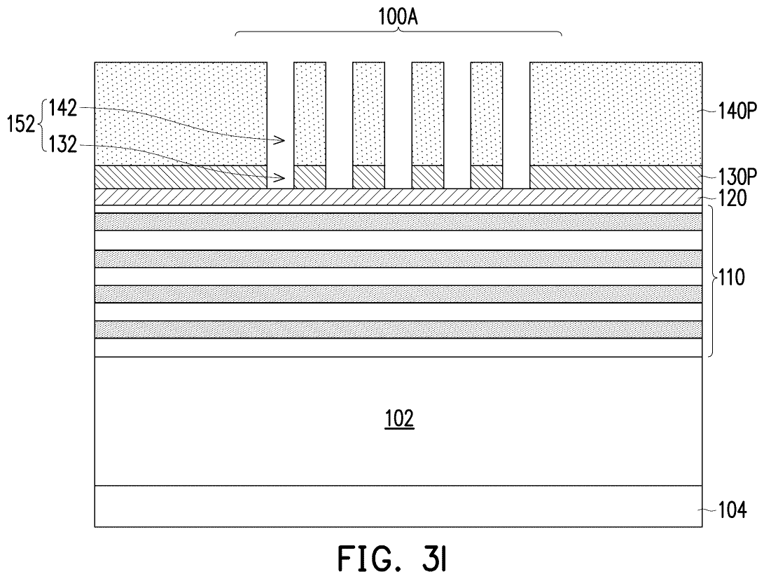

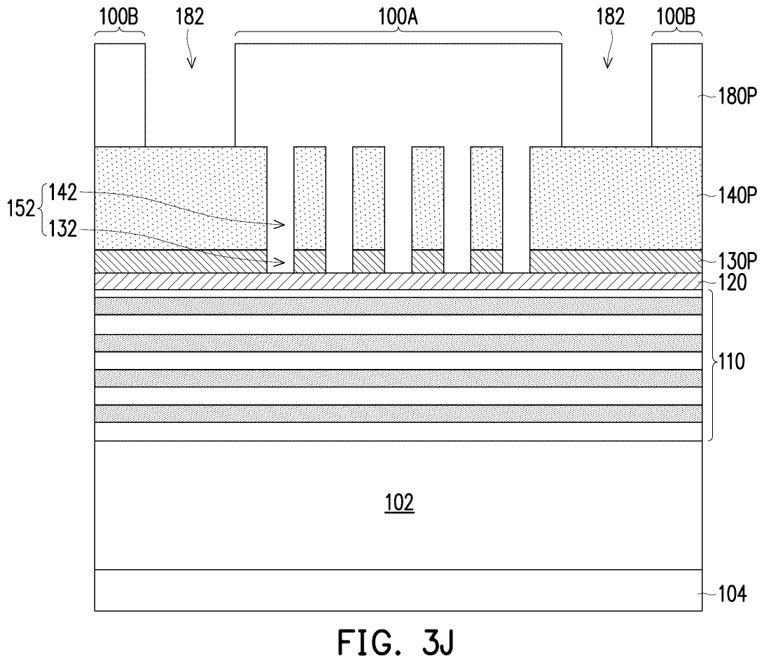

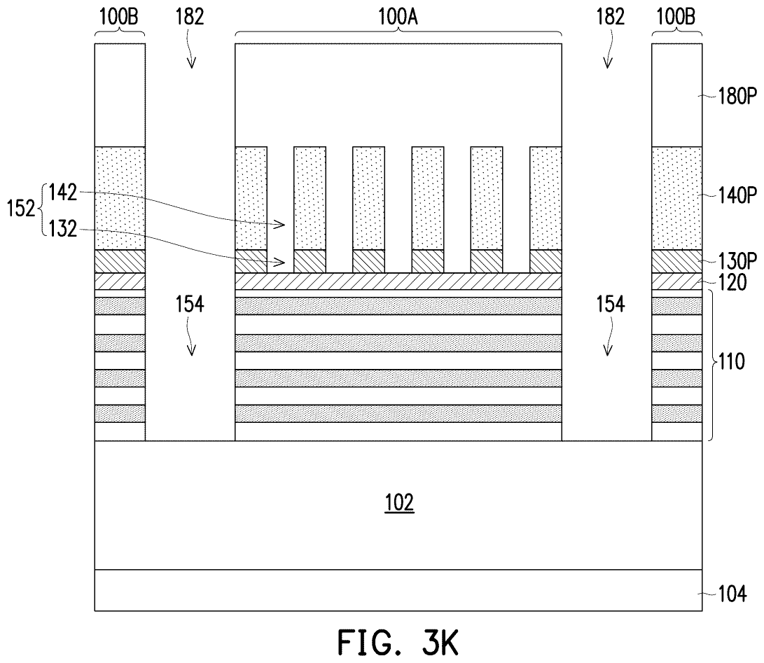

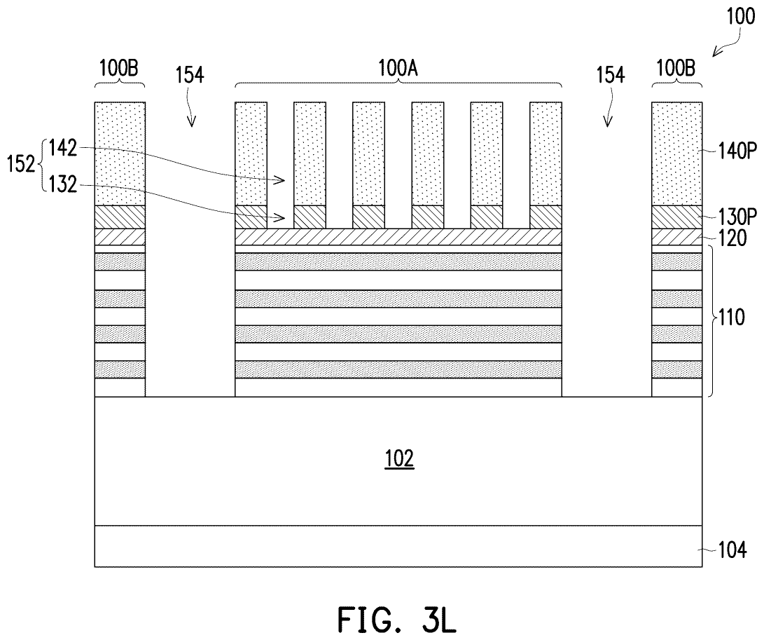

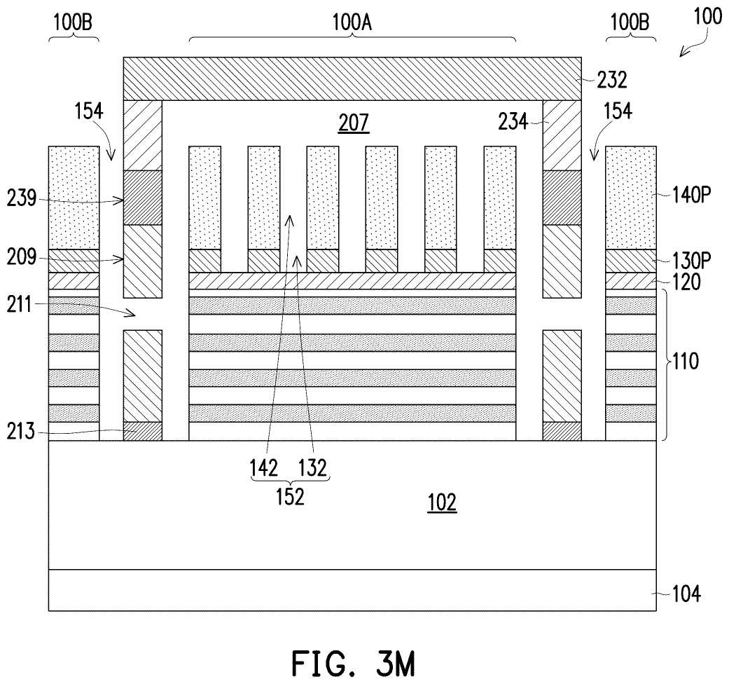

FIGS. 2A and 2B are a flowchart of a method 200 for fabricating an EUV mask with an embodiment of the present disclosure, for example, EUV mask 100. FIG. 3A through FIG. 3M are cross-sectional views of the EUV mask 100 at various stages of the fabrication process, in accordance with some embodiments. The method 200 is discussed in detail below, with reference to the EUV mask 100. In some embodiments, additional operations are performed before, during, and/or after the method 200, or some of the operations described are replaced and/or eliminated. In some embodiments, some of the features described below are replaced or eliminated. One of ordinary skill in the art would understand that although some embodiments are discussed with operations performed in a particular order, these operations may be performed in another logical order.

Referring to FIGS. 2A and 3A, the method 200 includes operation 202, in which a reflective multilayer stack 110 is formed over a substrate 102, in accordance with some embodiments. FIG. 3A is a cross-sectional view of an initial structure of an EUV mask 100 after forming the reflective multilayer stack 110 over the substrate 102, in accordance with some embodiments.

Referring to FIG. 3A, the initial structure of the EUV mask 100 includes a substrate 102 made of glass, silicon, quartz, or other low thermal expansion materials. The low thermal expansion material helps to minimize image distortion due to mask heating during use of the EUV mask 100. In some embodiments, the substrate 102 includes fused silica, fused quartz, calcium fluoride, silicon carbide, black diamond, or titanium oxide doped silicon oxide (SiO₂/TiO₂). In some embodiments, the substrate 102 has a thickness ranging from about 1 mm to about 7 mm. If the thickness of the substrate 102 is too small, a risk of breakage or warping of the EUV mask 100 increases, in some instances. On the other hand, if the thickness of the substrate is too great, a weight of the EUV mask 100 is needlessly increased, in some instances.

In some embodiments, a conductive layer 104 is disposed on a back surface of the substrate 102. In some embodiments, the conductive layer 104 is in direct contact with the back surface of the substrate 102. The conductive layer 104 is adapted to provide for electrostatically coupling of the EUV mask 100 to an electrostatic mask chuck (not shown) during fabrication and use of the EUV mask 100. In some embodiments, the conductive layer 104 includes chromium nitride (CrN) or tantalum boride (TaB). In some embodiments, the conductive layer 104 is formed by a deposition process such as, for example, chemical vapor deposition (CVD), plasma-enhanced chemical vapor deposition (PECVD), or physical vapor deposition (PVD). The thickness of the conductive layer 104 is controlled such that the conductive layer 104 is optically transparent.

The reflective multilayer stack 110 is disposed over a front surface of the substrate 102 opposite the back surface. In some embodiments, the reflective multilayer stack 110 is in direct contact with the front surface of the substrate 102. The reflective multilayer stack 110 provides a high reflectivity to the EUV light. In some embodiments, the reflective multilayer stack 110 is configured to achieve about 60% to about 75% reflectivity at the peak EUV illumination wavelength, e.g., the EUV illumination at 13.5 nm. Specifically, when the EUV light is applied at an incident angle of 6° to the surface of the reflective multilayer stack 110, the maximum reflectivity of light in the vicinity of a wavelength of 13.5 nm is about 60%, about 62%, about 65%, about 68%, about 70%, about 72%, or about 75%.

In some embodiments, the reflective multilayer stack 110 includes alternatively stacked layers of a high refractive index material and a low refractive index material. A material having a high refractive index tends to scatter EUV light on the one hand, and a material having a low refractive index tends to transmit EUV light on the other hand. Pairing these two type materials together provides a resonant reflectivity. In some embodiments, the reflective multilayer stack 110 includes alternatively stacked layers of molybdenum (Mo) and silicon (Si). In some embodiments, the reflective multilayer stack 110 includes alternatively stacked Mo and Si layers with Si being in the topmost layer. In some embodiments, a molybdenum layer is in direct contact with the front surface of the substrate 102. In other some embodiments, a silicon layer is in direct contact with the front surface of the substrate 102. Alternatively, the reflective multilayer stack 110 includes alternatively stacked layers of Mo and beryllium (Be).

The thickness of each layer in the reflective multilayer stack 110 depends on the EUV wavelength and the incident angle of the EUV light. The thickness of alternating layers in the reflective multilayer stack 110 is tuned to maximize the constructive interference of the EUV light reflected at each interface and to minimize the overall absorption of the EUV light. In some embodiments, the reflective multilayer stack 110 includes from 30 to 60 pairs of alternating layers of Mo and Si. Each Mo/Si pair has a thickness ranging from about 2 nm to about 7 nm, with a total thickness ranging from about 100 nm to about 300 nm.

In some embodiments, each layer in the reflective multilayer stack 110 is deposited over the substrate 102 and underlying layer using ion beam deposition (IBD) or DC magnetron sputtering. The deposition method used helps to ensure that the thickness uniformity of the reflective multilayer stack 110 is better than about 0.85 across the substrate 102. For example, to form a Mo/Si reflective multilayer stack 110, a Mo layer is deposited using a Mo target as the sputtering target and an argon (Ar) gas (having a gas pressure of from 1.3×10−2 Pa to 2.7×10−2 Pa) as the sputtering gas with an ion acceleration voltage of from 300 V to 1,500 V at a deposition rate of from 0.03 to 0.30 nm/see and then a Si layer is deposited using a Si target as the sputtering target and an Ar gas (having a gas pressure of 1.3×10⁻² Pa to 2.7×10⁻² Pa) as the sputtering gas, with an ion acceleration voltage of from 300 V to 1,500 V at a deposition rate of from 0.03 to 0.30 nm/sec. By stacking Si layers and Mo layers in 40 to 50 cycles, each of the cycles comprising the above steps, the Mo/Si reflective multilayer stack is deposited.

Referring to FIGS. 2A and 3B, the method 200 proceeds to operation 204, in which a capping layer 120 is deposited over the reflective multilayer stack 110, in accordance with some embodiments. FIG. 3B is a cross-sectional view of the structure of FIG. 3A after depositing the capping layer 120 over the reflective multilayer stack 110, in accordance with some embodiments.

Referring to FIG. 3B, the capping layer 120 is disposed over the topmost surface of the reflective multilayer stack 110. The capping layer 120 helps to protect the reflective multilayer stack 110 from oxidation and any chemical etchants to which the reflective multilayer stack 110 may be exposed during subsequent mask fabrication processes.

In some embodiments, the capping layer 120 includes a material that resists oxidation and corrosion and has a low chemical reactivity with common atmospheric gas species such as oxygen, nitrogen, and water vapor. In some embodiments, the capping layer 120 includes a transition metal such as, for example, ruthenium (Ru), iridium (Ir), rhodium (Rh), platinum (Pt), palladium (Pd), osmium (Os), rhenium (Re), vanadium (V), tantalum (Ta), hafnium (Hf), tungsten (W), molybdenum (Mo), zirconium (Zr), manganese (Mn), technetium (Tc), or alloys thereof.

In some embodiments, the capping layer 120 is formed using a deposition process such as, for example, IBD, chemical vapor deposition (CVD), physical vapor deposition (PVD), or atomic layer deposition (ALD). In instances where a Ru layer is to be formed as the capping layer 120 using IBD, the deposition may be carried out in an Ar atmosphere by using a Ru target as the sputtering target.

Referring to FIGS. 2A and 3C, the method 200 proceeds to an optional operation 206, in which an optional buffer layer 130 is deposited over the capping layer 120, in accordance with some embodiments. FIG. 3C is a cross-sectional view of the structure of FIG. 3B after depositing the buffer layer 130 over the capping layer 120, in accordance with some embodiments. In other embodiments where optional operation 206 is omitted, optional buffer layer 130 is absent. The following description describes embodiments that include the optional buffer layer 130; however, the description is equally applicable to embodiments that do not include optional buffer layer 130.

Referring to FIG. 3C, the optional buffer layer 130 is disposed on the capping layer 120. The optional buffer layer 130 possesses different etching characteristics from an absorber layer subsequently formed thereon, and thereby serves as an etch stop layer to prevent damages to the capping layer 120 during patterning of an absorber layer subsequently formed thereon. Further, the optional buffer layer 130 may also serve later as a sacrificial layer for focused ion beam repair of defects in the absorber layer. In some embodiments, the optional buffer layer 130 includes ruthenium boride (RuB), ruthenium silicide (RuSi), chromium oxide (CrO), or chromium nitride (CrN). In some other embodiments, the optional buffer layer 130 includes a dielectric material such as, for example, silicon oxide or silicon oxynitride. In some embodiments, the optional buffer layer 130 is deposited by CVD, PECVD, or PVD. In some embodiments, the optional buffer layer has a thickness ranging from about 2 to 10 nm. Embodiments in accordance with the present disclosure are not limited to EUV masks that include an optional buffer layer that has a thickness from two to about 10 nm.

Referring to FIGS. 2A and 3D, the method 200 proceeds to operation 208, in which an absorber layer 140 is deposited, over the buffer layer 130 if present, or if the buffer layer is not present onto capping layer 120, in accordance with various embodiments. FIG. 3D is a cross-sectional view of the structure of FIG. 3C after depositing the absorber layer 140 over the optional buffer layer 130, in accordance with some embodiments.

Referring to FIG. 3D, the absorber layer 140 is disposed in direct contact with the buffer layer 130. When optional buffer layer 130 is not present, the absorber layer 140 is in direct contact capping layer 120. The absorber layer 140 is usable to absorb radiation in the EUV wavelength projected onto the EUV mask 100.

The absorber layer 140 includes an absorber material having a high extinction coefficient K and a low refractive index n for EUV wavelengths. In some embodiments, the absorber layer 140 includes an absorber material having a high extinction coefficient and a low refractive index at 13.5 nm wavelength. In some embodiments, the extinction coefficient K of the absorber material of the absorber layer 140 is greater than 0.01, e.g., in a range from about 0.01 to 0.08. In some embodiments, the refractive index n of the absorber material of the absorber layer 140 is in a range from 0.87 to 1. In accordance with some embodiments of the present disclosure, the index of refraction and the extinction coefficient are in relation to light having a wavelength of about 13.5 nm. In accordance with some embodiments, the thickness of absorber layer 140 is less than about 80 nm. In accordance with other embodiments, the thickness of absorber layer 140 is less than about 60 nm. Other embodiments utilize an absorber layer 140 that is less than about 50 nm.

In some embodiments, the absorber material is in a polycrystalline state characterized by grains, grain boundaries and different phases of formation. In other embodiments, the absorber material is in an amorphous state characterized by grains on the order of less than 5 nanometers or less than 3 nanometers, no grain boundaries, and a single phase. In some embodiments, absorber layer 140 includes a first layer of absorber material and a second layer of absorber material different from the first layer of absorber material wherein the absorber material of the first layer has an index of refraction less than about 0.95 and an extinction coefficient of greater than 0.01, e.g., with respect to EUV having a wavelength of about 13.5 nm. In some embodiments, the absorber material of the second layer has a similar index of refraction and extinction coefficient properties. In some embodiments of the present disclosure, the absorber layer 140 includes more than two individual layers of absorber material. For example, in some embodiments, absorber layer 140 includes three, four, or more individual layers of absorber material, for example, five, six, or even more layers. In some embodiments, the composition of each of the different layers of absorber material is different. In some embodiments which include three or more layers of absorber material, the composition of alternating layers of absorber material may be the same or they may be different. In addition, in some embodiments, the thickness of one or more of the individual layers of absorber material are the same. In other embodiments, the thickness of some or all of the individual layers of absorber material are different. In some embodiments, the thickness of the individual layers of absorber material ranges between about 20 to 50 nm. In other embodiments, the thickness of individual layers of absorber material ranges between about 5 and 30 nm. In other embodiments, the thickness of individual layers of absorber material ranges between about 5 and 20 nm.

In other embodiments, the absorber layer 140 includes a single layer of absorber material.

The absorber layer 140 is formed by deposition techniques such as PVD, CVD, ALD, RF magnetron sputtering, DC magnetron sputtering, or IBD. The deposition process can be carried out in the presence of elements described as interstitial elements, such as B or N. Carrying out the deposition in the presence of the interstitial elements results in the interstitial elements being incorporated into the material of the absorber layer 140.

Different materials may be used to etch the absorber materials of the present disclosure and different materials may be used as hard mask layer with the different absorber materials. For example, in some embodiments, the absorber layer 140 is dry etched with a gas that contains chlorine, such as Cl₂ or BCl₃, or with a gas that contains fluorine, such as NF₃. Ar may be used as a carrier gas. In some embodiments, oxygen (O₂) may also be included as the carrier gas. For example, a chlorine-based etchant, chlorine-based plus oxygen etchant, or a mixture of a chlorine-based and fluorine based (e.g., carbon tetrafluoride and carbon tetrachloride) etchant will etch absorber materials including alloys that include a main alloy element comprising ruthenium (Ru), chromium (Cr), tantalum (Ta), platinum (Pt) or gold (Au), and at least one alloying element selected from ruthenium (Ru), chromium (Cr), tantalum (Ta), platinum (Pt), palladium (Pd), tungsten (W), gold (Au), iridium (Ir), niobium (Nb), rhodium (Rh), molybdenum (Mo), hafnium (Hf) or vanadium (V). In with some embodiments, a fluorine-based etchant is suitable to etch the alloys that include a main alloy element comprising iridium (Ir), titanium (Ti), niobium (Ni) or rhodium (Rh) and at least one alloying element selected from boron (B), nitrogen (N), silicon (Si), tantalum (Ta), zirconium (Zr), niobium (Ni), molybdenum (Mo), rhodium (Rh), titanium (Ti) or ruthenium (Ru). In some embodiments, a fluorine-based or a fluorine-based plus oxygen etchant is suitable to etch the alloys that include a main alloy element comprising molybdenum (Mo), tungsten (W) or palladium (Pd) and at least one alloying element selected from ruthenium (Ru), palladium (Pd), tungsten (W), iridium (Ir), titanium (Ti), niobium (Nb), rhodium (Rh), molybdenum (Mo), silicon (Si) or zirconium (Zr).

In accordance with some embodiments, SiN, TaBO, TaO, SiO, SiON, and SiOB are examples of materials useful as hard mask layer 160 and buffer layer 130 for absorber layer 140 utilizing alloys that include a main alloy element comprising ruthenium (Ru), chromium (Cr), tantalum (Ta), platinum (Pt) or gold (Au), and at least one alloying element selected from ruthenium (Ru), chromium (Cr), tantalum (Ta), platinum (Pt), palladium (Pd), tungsten (W), gold (Au), iridium (Ir), niobium (Nb), rhodium (Rh), molybdenum (Mo), hafnium (Hf) or vanadium (V). CrO and CrON are examples of materials useful for hard mask layer 160 and buffer layer 130 of an absorber layer 140 that utilizes alloys that include a main alloy element comprising iridium (Ir), titanium (Ti), niobium (Ni) or rhodium (Rh) and at least one alloying element selected from boron (B), nitrogen (N), silicon (Si), tantalum (Ta), zirconium (Zr), niobium (Ni), molybdenum (Mo), rhodium (Rh), titanium (Ti) or ruthenium (Ru). SiN, TaBO, TaO, CrO, and CrON are examples of materials useful for hard mask layer 160 and buffer layer 130 of an absorber layer 140 that utilizes alloys that include a main alloy element comprising molybdenum (Mo), tungsten (W) or palladium (Pd) and at least one alloying element selected from ruthenium (Ru), palladium (Pd), tungsten (W), iridium (Ir), titanium (Ti), niobium (Nb), rhodium (Rh), molybdenum (Mo), silicon (Si) or zirconium (Zr). In some embodiments, the same material may be used for hard mask layer 160 and buffer layer 130. In other embodiments, the material of hard mask layer 160 is different from the material of buffer layer 130. Embodiments in accordance with the present invention are not limited to the foregoing types of material for buffer layer 130 and hard mask layer 160.

In some embodiments, the absorber layer 140 includes or is made of a Ta-based alloy comprised of Ta and at least one alloying element. In some embodiments, the Ta-based alloy is a Ta-rich alloy having a Ta concentration ranging from greater than 50 atomic % and up to 90 atomic %. In other embodiments, the Ta-based alloy is an alloying element-rich alloy having an alloying element concentration ranging from more than 50 atomic % and up to 90 atomic %.

In some embodiments, the Ta-based alloy is comprised of Ta and at least one transition metal element. Examples of transition metal elements include, but are not limited to titanium (Ti), zirconium (Zr), hafnium (Hf), vanadium (V), niobium (Nb), chromium (Cr), molybdenum (Mo), tungsten (W), iron (Fe), ruthenium (Ru), cobalt (Co), rhodium (Rh), iridium (Ir), nickel (Ni), palladium (Pd), platinum (Pt), and gold (Au). In some embodiments, the Ta-based alloy includes tantalum chromium (TaCr), tantalum hafnium (TaHf), tantalum iridium (TaIr), tantalum nickel (TaNi), tantalum ruthenium (TaRu), tantalum cobalt (TaCo), tantalum gold (TaAu), tantalum molybdenum (TaMo), tantalum tungsten (TaW), tantalum iron (TaFe), tantalum rhodium (TaRh), tantalum vanadium (TaV), tantalum niobium (TaNb), tantalum palladium (TaPd), tantalum zirconium (TaZr), tantalum titanium (TaTi), or tantalum platinum (TaPt). Other examples of tantalum-based alloys include nitrides, oxides, borides, and carbides of the foregoing examples of tantalum based alloys, for example, tantalum chromium nitride (TaCrN) or tantalum chromium oxynitride (TaCrON).

In some embodiments, the Ta-based alloy is further doped with one or more interstitial elements such as boron (B), carbon (C), nitrogen (N), and oxygen (O). The interstitial element dopants increase the material density, which leads to an increase in the strength of the resulting alloy. In some embodiments, the absorber layer 140 is comprised of Ta, the alloying element and nitrogen. For example, in some embodiments, the absorber layer 140 includes TaCrN, TaHfN, TaIrN, TaNiN, TaRuN, TaCoN, TaAuN, TaMoN, TaWN, TaFeN, TaRhN, TaVN, TaNbN, TaPdN, TaZrN, TaTiN, TaPtN, or TaSiN. In some embodiments, the absorber layer 140 is comprised of Ta, the alloying element, nitrogen, and oxygen. For example, in some embodiments, the absorber layer 140 includes TaCrON, TaHfON, TaIrON, TaNiON, TaRuON, TaCoON, TaAuON, TaMoON, TaWON, TaFeON, TaRhON, TaVON, TaNbON, TaPdON, TaZrON, TaTiON, TaPtON, or TaSiON.

In some embodiments, the absorber layer 140 is deposited as an amorphous layer. By maintaining an amorphous phase, the overall roughness of the absorber layer 140 is improved. The thickness of the absorber layer 140 is controlled to provide between 95% and 99.5% absorption of the EUV light at 13.5 nm. In some embodiments, the absorber layer 140 may have a thickness ranging from about 5 nm to about 100 nm. If the thickness of the absorber layer 140 is too small, the absorber layer 140 is not able to absorb a sufficient amount of the EUV light to generate contrast between the reflective areas and non-reflective areas. On the other hand, if the thickness of the absorber layer 140 is too great, the precision of a pattern to be formed in the absorber layer 140 may be too low.

In embodiments of the present disclosure, by using alloys in accordance with embodiments of the present disclosure having a high extinction coefficient K as the absorber material, the mask 3D effects caused by EUV phase distortion can be reduced. As a result, the best focus shifts and pattern placement error can be reduced, while the normalized image log-slope (NILS) can be increased.

Referring to FIGS. 2A and 3E, the method 200 proceeds to operation 210, in which a resist stack including a hard mask layer 160 and a photoresist layer 170 is deposited over the absorber layer 140, in accordance with some embodiments. FIG. 3E is a cross-sectional view of the structure of FIG. 3D after sequentially depositing the hard mask layer 160 and the photoresist layer 170 over the absorber layer 140, in accordance with some embodiments.

Referring to FIG. 3E, the hard mask layer 160 is disposed over the absorber layer 140. In some embodiments, the hard mask layer 160 is in direct contact with the absorber layer 140. In some embodiments, the hard mask layer 160 includes a dielectric oxide such as silicon dioxide or a dielectric nitride such as silicon nitride. In some embodiments, the hard mask layer 160 is formed using a deposition process such as, for example, CVD, PECVD, or PVD. In some embodiments, the hard mask layer 160 has a thickness ranging from about 2 to 10 nm. Embodiments in accordance with the present disclosure are not limited to hard mask layer 160 having a thickness ranging from about 2 to 10 nm.

The photoresist layer 170 is disposed over the hard mask layer 160. The photoresist layer 170 includes a photosensitive material operable to be patterned by radiation. In some embodiments, the photoresist layer 170 includes a positive-tone photoresist material, and a negative-tone photoresist material or a hybrid-tone photoresist material. In some embodiments, the photoresist layer 170 is applied to the surface of the hard mask layer 160, for example, by spin coating.

Referring to FIGS. 2A and 3F, the method 200 proceeds to operation 212, in which the photoresist layer 170 is lithographically patterned to form a patterned photoresist layer 170P, in accordance with some embodiments. FIG. 3F is a cross-sectional view of the structure of FIG. 3E after lithographically patterning the photoresist layer 170 to form the patterned photoresist layer 170P, in accordance with some embodiments.

Referring to FIG. 3F, the photoresist layer 170 is patterned by first subjecting the photoresist layer 170 to a pattern of irradiation. Next, the exposed or unexposed portions of the photoresist layer 170 are removed depending on whether a positive-tone or negative-tone resist is used in the photoresist layer 170 with a resist developer, thereby forming the patterned photoresist layer 170P having a pattern of openings 172 formed therein. The openings 172 expose portions of the hard mask layer 160. The openings 172 are located in the pattern region 100A and correspond to locations where the pattern of openings 152 are present in the EUV mask 100 (FIG. 1A).

Referring to FIGS. 2A and 3G, the method 200 proceeds to operation 214, in which the hard mask layer 160 is etched using the patterned photoresist layer 170P as an etch mask to form a patterned hard mask layer 160P, in accordance with some embodiments. FIG. 3G is a cross-sectional view of the structure of FIG. 3F after etching the hard mask layer 160 to form the patterned hard mask layer 160P, in accordance with some embodiments.

Referring to FIG. 3G, portions of the hard mask layer 160 that are exposed by the openings 172 are etched to form openings 162 extending through the hard mask layer 160. The openings 162 expose portions of the underlying absorber layer 140. In some embodiments, the hard mask layer 160 is etched using an anisotropic etch. In some embodiments, the anisotropic etch is a dry etch such as, for example, reactive ion etch (RIE), a wet etch, or a combination thereof. The etch removes the material providing the hard mask layer 160 selective to the material providing the absorber layer 140. The remaining portions of the hard mask layer 160 constitute the patterned hard mask layer 160P. If not completely consumed during the etching of the hard mask layer 160, after etching the hard mask layer 160, the patterned photoresist layer 170P is removed from the surfaces of the patterned hard mask layer 160P, for example, using wet stripping or plasma ashing.

Referring to FIGS. 2A and 3H, the method 200 proceeds to operation 216, in which the absorber layer 140 is etched using the patterned hard mask layer 160P as an etch mask to form a patterned absorber layer 140P, in accordance with some embodiments. FIG. 3H is a cross-sectional view of the structure of FIG. 3G after etching the absorber layer 140 to form the patterned absorber layer 140P, in accordance with some embodiments.

Referring to FIG. 3H, portions of the absorber layer 140 that are exposed by the openings 162 are etched to form openings 142 extending through the absorber layer 140. The openings 142 expose portions of the underlying buffer layer 130. In some embodiments, the absorber layer 140 is etched using an anisotropic etching process. In some embodiments, the anisotropic etch is a dry etch such as, for example, RIE, a wet etch, or a combination thereof that removes the material providing the absorber layer 140 selective to the material providing the underlying buffer layer 130. For example, in some embodiments, the absorber layer 140 is dry etched with a gas that contains chlorine, such as Cl₂ or BCl₃, or with a gas that contains fluorine, such as NF₃. Ar may be used as a carrier gas. In some embodiments, oxygen (O₂) may also be included as the carrier gas. The etch rate and the etch selectivity depend on the etchant gas, etchant flow rate, power, pressure, and substrate temperature. After etching, the remaining portions of the absorber layer 140 constitute the patterned absorber layer 140P. In accordance with embodiments of the present disclosure, when absorber layer 140 includes multiple layers of absorber material as described below in more detail, when the individual layers of absorber material have differential etching properties, the individual layers of absorber material may be etched individually using different etchants. When the individual layers of absorber material do not have differential etching properties, the individual layers of absorber for material may be etched simultaneously.

Referring to FIGS. 2A and 3I, the method 200 proceeds to operation 218, in which the optional buffer layer 130 is etched using the patterned hard mask layer 160P as an etch mask to form a patterned buffer layer 130P, in accordance with some embodiments. FIG. 3I is a cross-sectional view of the structure of FIG. 3H after etching the optional buffer layer 130 to form the patterned optional buffer layer 130P, in accordance with some embodiments.

Referring to FIG. 3I, portions of the buffer layer 130 that are exposed by the openings 162 and 142 are etched to form openings 132 extending through the buffer layer 130. The openings 132 expose portions of the underlying capping layer 120. In some embodiments, the buffer layer 130 is etched using an anisotropic etching process. In some embodiments, the anisotropic etch is a dry etch such as, for example, RIE, a wet etch, or a combination thereof that removes the material providing the buffer layer 130 selective to the material providing the capping layer 120. The remaining portions of the buffer layer 130 constitute the patterned buffer layer 130P. After etching the buffer layer 130, the patterned hard mask layer 160P is removed from the surfaces of the patterned absorber layer 140P, for example, using oxygen plasma or a wet etch.

The openings 142 in the patterned absorber layer 140P and respective underlying openings 132 in the patterned buffer layer 130P together define the pattern of openings 152 in the EUV mask 100.

Referring to FIGS. 2A and 3J, the method 200 proceeds to operation 220, in which a patterned photoresist layer 180P comprising a pattern of openings 182 is formed over the patterned absorber layer 140P and the patterned buffer layer 130P, in accordance with some embodiments. FIG. 3J is a cross-sectional view of the structure of FIG. 3I after forming the patterned photoresist layer 180P comprising openings 182 over the patterned absorber layer 140P and the patterned buffer layer 130P, in accordance with some embodiments.

Referring to FIG. 3J, the openings 182 expose portions of the patterned absorber layer 140P at the periphery of the patterned absorber layer 140P. The openings 182 correspond to the trenches 154 in the peripheral region 100B of the EUV mask 100 that are to be formed. To form the patterned photoresist layer 180P, a photoresist layer (not shown) is applied over the patterned buffer layer 130P and the patterned absorber layer 140P. The photoresist layer fills the openings 132 and 142 in the patterned buffer layer 130P and the patterned absorber layer 140P, respectively. In some embodiments, the photoresist layer includes a positive-tone photoresist material, a negative-tone photoresist material, or a hybrid-tone photoresist material. In some embodiments, the photoresist layer includes a same material as the photoresist layer 170 described above in FIG. 3E. In some embodiments, the photoresist layer includes a different material from the photoresist layer 170. In some embodiments, the photoresist layer is formed, for example, by spin coating. The photoresist layer is subsequently patterned by exposing the photoresist layer to a pattern of radiation, and removing the exposed or unexposed portions of the photoresist layer using a resist developer depending on whether a positive or negative resist is used. The remaining portions of the photoresist layer constitute the patterned photoresist layer 180P.

Referring to FIGS. 2A and 3K, the method 200 proceeds to operation 222, in which the patterned absorber layer 140P, the patterned buffer layer 130P if present, the capping layer 120, and the reflective multilayer stack 110 are etched using the patterned photoresist layer 180P as an etch mask to form trenches 154 in the peripheral region 100B of the substrate 102, in accordance with some embodiments. FIG. 3K is a cross-sectional view of the structure of FIG. 3J after etching the patterned absorber layer 140P, the patterned buffer layer 130P if present, the capping layer 120, and the reflective multilayer stack 110, to form the trenches 154 in the peripheral region 100B of the substrate 102, in accordance with some embodiments.

Referring to FIG. 3K, the trenches 154 extend through the patterned absorber layer 140P, the patterned buffer layer 130P if present, the capping layer 120, and the reflective multilayer stack 110 to expose the surface of the substrate 102. The trenches 154 surround the pattern region 100A of the EUV mask 100, separating the pattern region 100A from the peripheral region 100B.

In some embodiments, the patterned absorber layer 140P, the patterned buffer layer 130P, the capping layer 120, and the reflective multilayer stack 110 are etched using a single anisotropic etching process. The anisotropic etch can be a dry etch such as, for example, RIE, a wet etch, or a combination thereof that removes materials of the respective patterned absorber layer 140P, the patterned buffer layer 130P, the capping layer 120, and the reflective multilayer stack 110, selective to the material providing the substrate 102. In some embodiments, the patterned absorber layer 140P, the patterned buffer layer 130P, the capping layer 120, and the reflective multilayer stack 110 are etched using multiple distinct anisotropic etching processes. Each anisotropic etch can be a dry etch such as, for example, RIE, a wet etch, or a combination thereof.

Referring to FIGS. 2A and 3L, the method 200 proceeds to operation 224, in which the patterned photoresist layer 180P is removed, in accordance with some embodiments. FIG. 3L is a cross-sectional view of the structure of FIG. 3K after removing the patterned photoresist layer 180P, in accordance with some embodiments.

Referring to FIG. 3L, the patterned photoresist layer 180P is removed from the pattern region 100A and the peripheral region 100B of the substrate 102, for example, by wet stripping or plasma ashing. The removal of the patterned photoresist layer 180P from the openings 142 in the patterned absorber layer 140P and the openings 132 in the patterned buffer layer 130P re-exposes the surfaces of the capping layer 120 in the pattern region 100A.

An EUV mask 100 is thus formed. The EUV mask 100 includes a substrate 102, a reflective multilayer stack 110 over a front surface of the substrate 102, a capping layer 120 over the reflective multilayer stack 110, a patterned buffer layer 130P over the capping layer 120, and a patterned absorber layer 140P over the patterned buffer layer 130P. The EUV mask 100 further includes a conductive layer 104 over a back surface of the substrate 102 opposite the front surface. The patterned absorber layer 140P includes an alloy having a high extinction coefficient, which allows forming a thinner layer. The mask 3D effects caused by the thicker absorber layer can thus be reduced and unnecessary EUV light can be eliminated. As a result, a pattern on the EUV mask 100 can be projected precisely onto a silicon wafer.

After removal of the patterned photoresist layer 180P, the EUV mask 100 is cleaned to remove any contaminants therefrom. In some embodiments, the EUV mask 100 is cleaned by submerging the EUV mask 100 into an ammonium hydroxide (NH₄OH) solution. In some embodiments, the EUV mask 100 is cleaned by submerging the EUV mask 100 into a diluted hydrofluoric acid (HF) solution.

The EUV mask 100 is subsequently radiated with, for example, an UV light with a wavelength of 193 nm, for inspection of any defects in the patterned region 100A. The foreign matters may be detected from diffusely reflected light. If defects are detected, the EUV mask 100 is further cleaned using suitable cleaning processes.

As illustrated in FIG. 3M, the pellicle 114 may be positioned over the photomask 100, thereby forming an enclosed inner volume 207 that is enclosed by the pellicle 114 and the photomask 100.

In some embodiments, the pellicle 114 includes a pellicle frame 209 that may be positioned on the mask substrate 102. The pellicle frame 209 may be designed in various dimensions, shapes, and configurations. In some embodiments, the pellicle frame 209 may have a round shape, a rectangular shape, or any other suitable shape. In some embodiments, the pellicle frame 209 may be formed from Si, SiC, SiN, glass, a low coefficient of thermal expansion material (such as an Al alloy, a Ti alloy, Invar, Kovar, or the like), another suitable material, or a combination thereof. In some embodiments, suitable processes for forming the pellicle frame 209 may include machining processes, sintering processes, photochemical etching processes, other applicable processes, or a combination thereof.

As further illustrated in FIG. 3M, the pellicle 114 may further include a vent structure 211 extending through the pellicle frame 209. In some embodiments, the vent structure 211 may comprise one or more apertures formed through the pellicle frame 209. The apertures may take any shape, including circular apertures, rectangular apertures, slit-shaped apertures, other shapes, or any combination thereof. The apertures may allow for a flow of air or other gases through a portion of the pellicle frame 209. In some embodiments, the apertures may include filters to minimize passage of outside particles through the vent structure 211. In some embodiments, the vent structure 211 may prevent the pellicle membrane from rupturing during the EUV lithography process.

As further illustrated in FIG. 3M, the pellicle frame 209 is attached to photomask substrate 102 by a pellicle frame adhesive 213. In some embodiments, the pellicle frame adhesive 213 may be formed from a crosslink type adhesive, a thermoplastic elastomer type adhesive, a polystyrene type adhesive, an acrylic type adhesive, a silicon-based adhesive, an epoxy type adhesive, or a combination thereof.

In some embodiments, a surface treatment may be performed on the pellicle frame 209 to enhance the adhesion of the pellicle frame 209 to the pellicle frame adhesive 213. In some examples, the surface treatment may include an oxygen plasma treatment, another applicable treatment, or a combination thereof. However, in other examples, no surface treatment may be performed on the pellicle frame 209.

As further illustrated in FIG. 3M, the pellicle 114 may further include a pellicle membrane assembly 230 including a pellicle membrane 232 and a membrane border 234 positioned over the pellicle frame 209. The pellicle membrane 232 extends over the pattern region of the photomask 100 to protect the pattern region from contaminant particles. Particles unintentionally deposited on the pattern region of the photomask 100 may introduce defects and result in degradation of the transferred patterns. Particles may be introduced by any of a variety of ways, such as during, a cleaning process, and/or during handling of the photomask 100. By keeping the contaminant particles out of the focal plane of the photomask 100, a high fidelity pattern transfer from the photomask 100 to a semiconductor wafer can be achieved.

As illustrated in FIG. 3M, a pellicle membrane adhesive 239 may be positioned between the membrane border 234 and the pellicle frame 209, attaching the pellicle membrane 232 to the pellicle frame 209. In some embodiments, the pellicle membrane adhesive 239 may be formed from a thermoplastic elastomer type adhesive, a polystyrene type adhesive, an acrylic type adhesive, a silicon-based adhesive, an epoxy type adhesive, another suitable adhesive, or a combination thereof. In some embodiments, the pellicle membrane adhesive 239 may be formed from a material that is different from the material making up the pellicle frame adhesive 213.

The membrane border 234 may be attached around the periphery of the pellicle membrane 232, and thus mechanically supports the pellicle membrane 232. The membrane border 234 may, in turn, be mechanically supported by an upper surface of the pellicle frame 209 when the pellicle-photomask structure is fully assembled. That is, the pellicle frame 209 may mechanically support the membrane border 234 and the pellicle membrane 232 on the substrate 102 of photomask 100.

In some embodiments, the membrane border 234 may be formed from Si. In further examples, the membrane border 234 may be formed from boron carbide, graphene, carbon nanotube, SiC, SiN, SiO₂, SiON, Zr, Nb, Mo, Cd, Ru, Ti, Al, Mg, V, Hf, Ge, Mn, Cr, W, Ta, Ir, Zn, Cu, F, Co, Au, Pt, Sn, Ni, Te, Ag, another suitable material, an allotrope of any of these materials, or a combination thereof.

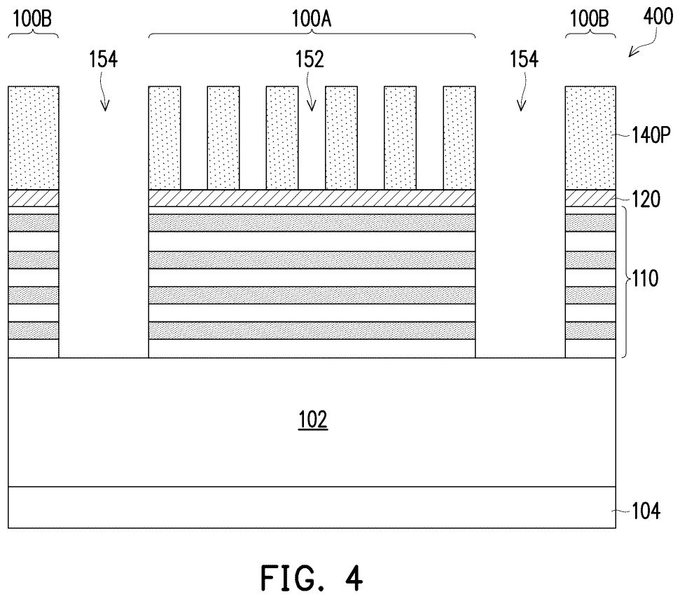

FIG. 4 is a cross-sectional view of an EUV mask 400, in accordance with a second embodiment of the present disclosure. Referring to FIG. 4, the EUV mask 400 includes a substrate 102, a reflective multilayer stack 110 over a front surface of the substrate 102, a capping layer 120 over the reflective multilayer stack 110, and a patterned absorber layer 140P over the capping layer 120. The EUV mask 400 further includes a conductive layer 104 over a back surface of the substrate 102 opposite the front surface. In comparison with the EUV mask 100 of FIG. 1A, the patterned buffer layer 130P is omitted in the EUV mask 400. Accordingly, in the EUV mask 400, the patterned absorber layer 140P is in direct contact with the capping layer 120.

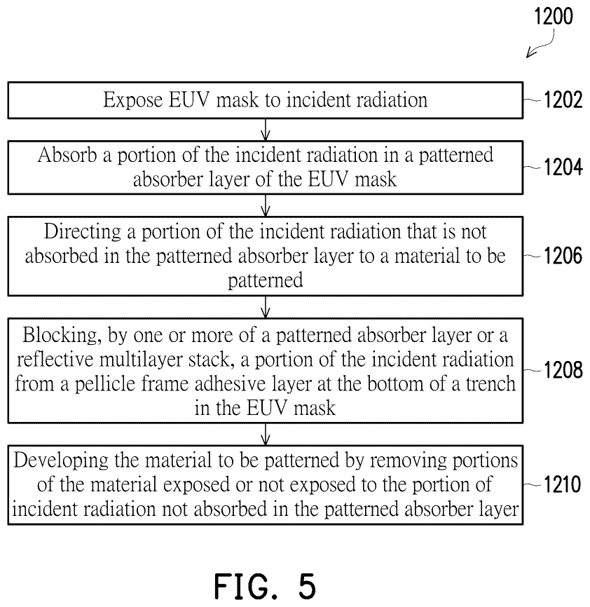

FIG. 5 illustrates a method 1200 of using an EUV mask in accordance with embodiments of the present disclosure. Method 1200 includes step 1202 of exposing an EUV mask to an incident radiation. An example of an EUV mask useful in step 1202 include the EUV masks described above. At step 1204, a portion of the incident radiation is absorbed in a patterned absorber layer of the EUV mask. A portion of the incident radiation that is not absorbed in the patterned absorber layer is directed to a material to be patterned in step 1206. After the material to be patterned has been exposed to the incident radiation from the EUV mask, portions of the material exposed or not exposed to the incident radiation from the EUV mask are removed in step 1208.

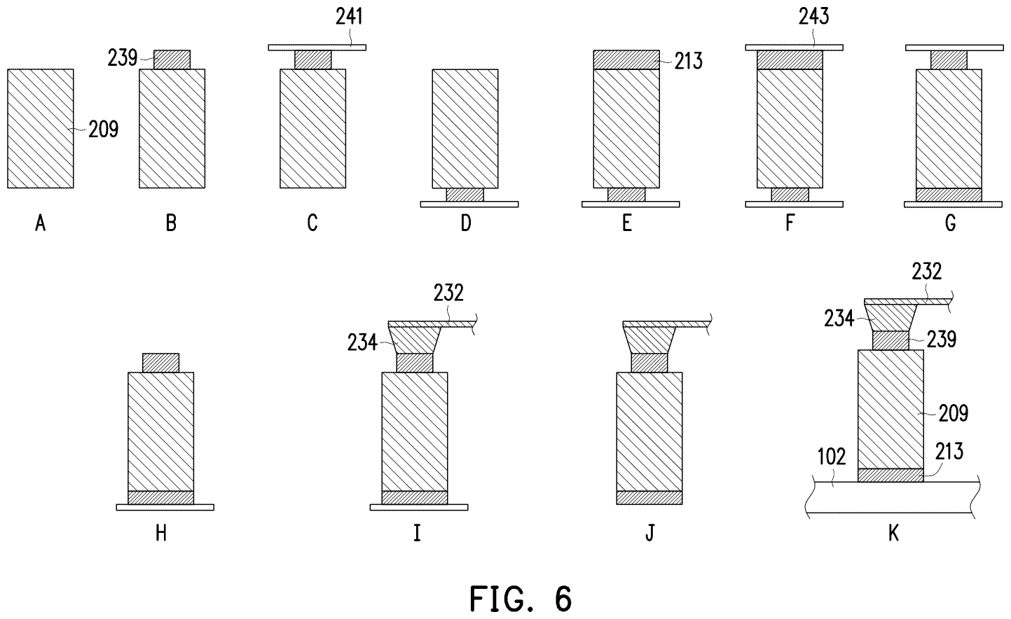

FIG. 2B includes operations 227 through 237 involved in attaching a pellicle frame 209 to pellicle membrane assembly 230 and substrate 102. FIG. 6 includes schematic cross-sectional views of the pellicle frame 209, pellicle membrane assembly 230 and substrate 102 during various steps of FIG. 2B. At operation 227, a pellicle frame 209 of A in FIG. 6 is formed and provided. In some embodiments, pellicle frame 209 is formed by known techniques from a metal material. At operation 229, ends of pellicle frame 209 which are to receive pellicle membrane adhesive and pellicle frame adhesive are treated to improve adhesion between the treated portions of pellicle frame 209 and the respective adhesives. At operation 231, pellicle membrane adhesive 239 is applied to one end of pellicle frame 209. The resulting structure is illustrated in B in FIG. 6. In C in FIG. 6, a liner 241 has been applied to an exposed portion of the pellicle membrane adhesive 239 to prevent pellicle membrane adhesive 239 sticking to unwanted materials. Pellicle frame 209 is then flipped as illustrated in D in FIG. 6 and then in accordance with operation 233, pellicle frame adhesive 213 is applied to an opposite end of pellicle frame 209. In F in FIG. 6, a liner 243 has been applied to an exposed portion of the pellicle frame adhesive 213. After operation 233, the pellicle frame 209 including the two adhesive layers is flipped. The flipped pellicle frame including the two adhesive layers is illustrated in G in FIG. 6. In H in FIG. 6, the liner 241 has been removed. In operation 235, the exposed portion of pellicle membrane adhesive 239 is contacted with pellicle membrane border 234 which supports pellicle membrane 232. Pellicle membrane border 234 and pellicle membrane 232 are formed by known techniques, e.g., growth of a silicon substrate, formation of the membrane film on the silicon substrate and backside etching of the silicon substrate to thin a portion of the silicon substrate below the membrane film. I in FIG. 6 illustrates the pellicle membrane border 234 attached to pellicle membrane adhesive 239. J in FIG. 6 illustrates the pellicle frame 209 after the liner 243 has been removed. After liner 243 has been removed, at operation 237, the pellicle frame carrying the pellicle membrane assembly brought into contact with substrate 102. Pellicle frame adhesive 213 attaches pellicle frame 209 to substrate 102. See K in FIG. 6. In some embodiments, the pellicle membrane frame carrying the pellicle membrane assembly is attached to substrate 102 utilizing an accuracy mounter.

One aspect of this description relates to an EUV mask that includes a substrate with a reflective multilayer stack over the substrate. In this aspect of an EUV mask, a patterned absorber layer is over the reflective multilayer stack and a pellicle frame is on the substrate. Another aspect of this description relates to relates to a method of using an EUV mask. The method includes exposing the EUV mask to an incident radiation, the EUV mask including a substrate with a reflective multilayer stack over the substrate. The EUV mask also includes a patterned absorber layer over the reflective multilayer stack and a a trench in the reflective multilayer stack and the patterned absorber layer. A pellicle frame adhesive layer is on the substrate and at the bottom of the trench and a pellicle frame is on the pellicle frame adhesive layer. The method includes a step of absorbing a portion of the incident radiation in the patterned absorber layer and blocking, by one or more of the patterned absorber layer or the reflective multilayer stack, a portion of the incident radiation from the pellicle frame adhesive layer at the bottom of the trench. Another aspect of this description relates to relates to a method of forming an EUV mask. The method includes forming a reflective multilayer stack on a substrate and depositing a capping layer on the reflective multilayer stack. According to the method, a buffer layer is formed on the capping layer and a layer of absorber material is deposited on the buffer layer. A hard mask layer is formed on the layer of absorber material. The hard mask layer is etched to form a patterned hard mask layer. The layer of absorber material is etched using the patterned hard mask layer as an etch mask. The etching produces a plurality of openings in the layer of absorber material. The patterned hard mask layer is then removed and a trench is formed in the layer of absorber material, buffer layer, capping layer, and reflective multilayer stack. According to this method, a pellicle frame is then attached to the substrate in the trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An extreme ultraviolet (EUV) mask, comprising
a substrate a first surface and a second surface opposite the first surface;
a reflective multilayer stack on the first surface of the substrate, the reflective multilayer stack including:
a trench extending through the reflective multilayer stack, the trench being defined by plurality of inner sidewalls of the reflective multilayer stack and a plurality of outer sidewalls of the reflective multilayer stack;
a pattern region that is surrounded by the trench and is defined by the plurality of inner sidewalls; and
a peripheral region separated from the pattern region by the trench and is spaced outward from the trench;
a pellicle frame extends into and through the trench and is coupled to the first surface of the substrate by a first adhesive, the pellicle frame includes an end surface that is spaced apart from the substrate and faces away from the substrate;
a pellicle membrane assembly including:
a pellicle membrane overlapping the pattern region; and
a membrane border at the periphery of the pellicle membrane, the membrane border is coupled to the end surface of the pellicle frame by a second adhesive.

2. The EUV mask of claim 1, wherein the trench has a first rectangular profile.

3. The EUV mask of claim 2, wherein the pattern region has a second rectangular profile smaller than the first rectangular profile.

4. The EUV mask of claim 1, further comprising:
a conductive layer on the second surface of the substrate;
a capping layer stacked on the reflective multilayer stack; and
an absorber layer stacked on the capping layer, and
wherein the trench extends through the capping layer and the absorber layer.

5. The EUV mask of claim 4, wherein the trench is defined by:
respective inner sidewalls of the capping layer and the absorber layer coplanar with the plurality of inner sidewalls of the reflective multilayer stack; and
respective outer sidewalls of the capping layer and the absorber layer coplanar with the plurality of outer sidewalls of the reflective multilayer stack.

6. The EUV mask of claim 5, wherein the respective inner sidewalls of the capping layer and the absorber layer along with the plurality of inner sidewalls of the reflective multilayer stack are parallel with the respective outer sidewalls of the capping layer and the absorber layer along with the plurality of outer sidewalls of the reflective multilayer stack.

7. The EUV mask of claim 4, wherein one or more openings extend through the absorber layer exposing one or more regions of the capping layer from the absorber layer.

8. The EUV mask of claim 7, wherein the one or more openings define a pattern in the absorber layer.

9. The EUV mask of claim 1, further comprising:
a conductive layer on the second surface of the substrate;
a capping layer stacked on the reflective multilayer stack;
a buffer layer on the capping layer; and
an absorber layer stacked on the buffer layer, and
wherein the trench extends through the capping layer and the buffer layer.

10. The EUV mask of claim 9, wherein the trench is defined by:
respective inner sidewalls of the capping layer, the buffer layer, and the absorber layer coplanar with the plurality of inner sidewalls of the reflective multilayer stack; and
respective outer sidewalls of the capping layer, the buffer layer, and the absorber layer coplanar with the plurality of outer sidewalls of the reflective multilayer stack.

11. The EUV mask of claim 10, wherein the respective inner sidewalls of the capping layer, the buffer layer, and the absorber layer along with the plurality of inner sidewalls of the reflective multilayer stack are parallel with the respective outer sidewalls of the capping layer, the buffer layer, and the absorber layer along with the plurality of outer sidewalls of the reflective multilayer stack.

12. The EUV mask of claim 9, wherein one or more openings extend through the absorber layer and the buffer layer exposing one or more regions of the capping layer from the buffer layer and the absorber layer.

13. The EUV mask of claim 12, wherein the one or more openings define a pattern in the buffer layer and the absorber layer.

14. The EUV mask of claim 1, wherein the plurality of inner sidewalls are coplanar with the plurality of outer sidewalls.

15. An extreme ultraviolet (EUV) mask, comprising:
a substrate a first surface and a second surface opposite the first surface;
a reflective multilayer stack on the first surface of the substrate, the reflective multilayer stack including:
a trench extending through the reflective multilayer stack, the trench being defined by plurality of inner sidewalls of the reflective multilayer stack and a plurality of outer sidewalls of the reflective multilayer stack, the plurality of inner sidewalls are angled relative to the first surface of the substrate, and the plurality of outer sidewalls are angled relative to the first surface of the substrate;
a pattern region that is surrounded by the trench and is defined by the plurality of inner sidewalls; and
a peripheral region separated from the pattern region by the trench and is spaced outward from the trench;
a pellicle frame extends into and through the trench and is coupled to the first surface of the substrate by a first adhesive, the pellicle frame includes an end surface that is spaced apart from the substrate and faces away from the substrate;
a pellicle membrane assembly including:
a pellicle membrane overlapping the pattern region; and
a membrane border at the periphery of the pellicle membrane, the membrane border is coupled to the end surface of the pellicle frame by a second adhesive.

16. The EUV mask of claim 15, wherein the plurality of outer sidewalls are angled towards the frame, and the plurality of inner sidewalls are angled towards the frame.

17. The EUV mask of claim 15, wherein the plurality of inner sidewalls are angled towards the frame and the plurality of outer sidewalls are angled away from the frame.

18. The EUV mask of claim 15, wherein the plurality of inner sidewalls are angled away from the frame and the plurality of sidewalls are angled away from the frame.

19. An extreme ultraviolet (EUV) mask, comprising:
a substrate a first surface and a second surface opposite the first surface;
a reflective multilayer stack on the first surface of the substrate, the reflective multilayer stack including:
a trench extending through the reflective multilayer stack, the trench being defined by plurality of inner sidewalls of the reflective multilayer stack and a plurality of outer sidewalls of the reflective multilayer stack;
a pattern region that is surrounded by the trench and is defined by the plurality of inner sidewalls; and
a peripheral region separated from the pattern region by the trench and is spaced outward from the trench;
a thermal barrier layer within the trench, on a region of the first surface of the substrate aligned with the trench, and that extends from the plurality of inner sidewalls to the plurality of outer sidewalls of the reflective multilayer stack;
a pellicle frame extends into and through the trench and is coupled to the first surface of the thermal barrier layer by a first adhesive, the pellicle frame includes an end surface that is spaced apart from the substrate and faces away from the substrate;
a pellicle membrane assembly including:
a pellicle membrane overlapping the pattern region; and
a membrane border at the periphery of the pellicle membrane, the membrane border is coupled to the end surface of the pellicle frame by a second adhesive.

20. The device of claim 19, wherein the thermal barrier layer includes silicon or silicon dioxide.
